(19) United States
(12) Patent Application Publication
(10) Pub. No.: US 2003/0038681 A1
(43) Pub. Date: Feb. 27, 2003

(54) System and method of digital tuning a voltage controlled oscillator

(76) Inventors: Masoud Djafari, Marina Del Rey, CA (US); Duke T. Tran, Irvine, CA (US); Syed K. Enam, Mission Viejo, CA (US)

Correspondence Address: KNOBBE MARTENS OLSON & BEAR LLP, 2040 MAIN STREET, FOURTEENTH FLOOR, IRVINE, CA, 92614, US

(21) Appl. No.: 09/873,774

(22) Filed: Jun. 4, 2001

Related U.S. Application Data
(60) Provisional application No. 60/208,899, filed on Jun. 2, 2000.
(60) Provisional application No. 60/267,366, filed on Feb. 7, 2001.

(51) Int. Cl. H03L 7/00

(52) U.S. Cl. 331/1 A

(57) ABSTRACT

A voltage controlled oscillator in a clock multiply unit includes a plurality of varactors controlled by a plurality of respective control voltage signals. The plurality of varactors allows for a combination of efficient methods to set an output signal frequency for the voltage controlled oscillator. For example, a pair of independent varactors are controlled by a differential control voltage signal. Differential control improves noise immunity and fine tuning ranges of the voltage controlled oscillator. The voltage controlled oscillator determines an operating frequency range automatically at start-up or upon reset. For example, a digital coarse tuning circuit starts the voltage controlled oscillator oscillating at a frequency corresponding to a frequency in a lowest range of operating frequencies, compares an output generated by the voltage controlled oscillator with a reference signal, increases the oscillation frequency to a frequency in the next higher range if the frequency of the reference signal is higher than the frequency of the generated output, repeats the comparisons and possible increments for a predetermined number of times, and shuts down.

### PRIORITY CLAIMS

The benefit under 35 U.S.C. §119(e) of U.S. Provisional Application No. 60/208,899, filed Jun. 2, 2000, and entitled “MIXED MODE TRANSCEIVER” and of U.S. Provisional Application No. 60/267,366, filed Feb. 7, 2001, and entitled “TRANSCEIVER,” is hereby claimed.

### APPENDIX A

Appendix A, which forms a part of this disclosure, is a list of commonly owned copending U.S. patent applications. Each one of the applications listed in Appendix A is hereby incorporated herein in its entirety by reference thereto.

### COPYRIGHT RIGHTS

A portion of the disclosure of this patent document contains material that is subject to copyright protection. The copyright owner has no objection to the facsimile reproduction by anyone of the patent document or of the patent disclosure as it appears in the Patent and Trademark Office patent files or records, but otherwise reserves all copyright rights whatsoever.

### BACKGROUND OF THE INVENTION

1. Field of the Invention

The invention generally relates to networking. In particular, embodiments of the invention relate to network interfaces.

2. Description of the Related Art

Common electronic devices, including computers, printers, telephones, and televisions, are often interconnected so that they can communicate with one another. As time progresses, even greater numbers of devices are networked together, the devices themselves increase in speed, and more users rely upon networked connections. Thus, there is an ever-present need for increased data rates along networks that interconnect electronic devices.

Conventional circuits for communicating data at very high data rates have proven inadequate. Conventional circuits are relatively expensive to implement or are relatively slow in operation. Further, conventional systems employing present techniques are often relatively unstable in operation and are difficult to integrate with other systems. In addition, conventional circuits inefficiently consume relatively large amounts of power, thereby wasting power, requiring expensive circuit packaging, and increasing heat dissipation requirements.

Due to the inadequacies of the present art, users have had to pay for expensive network interfaces or have suffered from the frustration and the wasted time associated with low-speed systems.

### SUMMARY OF THE INVENTION

A voltage controlled oscillator (VCO) in a clock multiply unit includes a plurality of varactors (e.g., tuning capacitive elements) controlled by a plurality of respective control voltage signals. The VCO generates a differential output clock which is a multiple of an input clock. The plurality of varactors allows for a combination of efficient methods to set an output signal frequency for the voltage controlled oscillator. For example, a pair of independent varactors are controlled by a differential control voltage signal. In one embodiment, one of the independent varactors is coupled between a first polarity of the differential control voltage and a power supply, and the other independent varactor is coupled between a second polarity signal of the differential control voltage and ground.

Differential control improves noise immunity and fine tuning ranges of the voltage controlled oscillator. The VCO determines an operating frequency range automatically at start-up or upon reset. For example, a digital coarse tuning circuit starts the voltage controlled oscillator oscillating at a frequency corresponding to a frequency in a lowest range of operating frequencies, compares an output generated by the voltage controlled oscillator with a reference signal, increases the oscillation frequency to a frequency in the next higher range if the frequency of the reference signal is higher than the frequency of the generated output, repeats the comparisons and possible increments for a predetermined number of times, and shuts down.

In one embodiment, operational frequencies of the VCO are divided into multiple overlapping ranges. An automatic search for an operating frequency range includes starting the VCO with an oscillation frequency corresponding to a midpoint in the lowest range, comparing an output signal of the VCO with a reference signal, increasing the oscillation frequency to correspond to a midpoint of the next higher range if the frequency of the output signal is lower than the frequency of the reference signal, and repeating the comparison of the output signal to the reference signal and consequent increase in the oscillation frequency to correspond to the midpoint of the next higher range until the frequency of the output signal is higher than the frequency of the reference signal.

In one embodiment, the automatic search algorithm (or initialization of the VCO) is implemented with digital circuitry. The automatic search occurs upon powering up the VCO and a substantial portion of the digital circuitry is disabled (or powered down) at the end of the automatic search.

In one embodiment, the digital circuitry includes counters incremented by a reference clock and an internal clock generated by the VCO. For example, the counters are used to conduct a race between the reference clock and the internal clock. A comparison circuit detects occurrences of overflows in the first and second counters. For example, the relative timing of the overflows indicates which clock is faster.

An n-bit shift register with one of the bits initialized to ‘1’ and the remaining bits initialized to zero is shifted by one bit when the overflow of the counter updated by the reference clock leads the overflow of the counter updated by the internal clock within a specified time interval. The position of the ‘1’ in the n-bit shift register determines a voltage level of a control signal applied to the VCO. The digital circuitry includes a manual mode in which the n-bit shift register is directly controlled by an input signal to the digital circuitry.

In one embodiment, the first counter periodically resets the second counter. Therefore, the counters alternate between racing for a first time interval and resting for a second time interval. In one embodiment, the counters and the comparison circuit are disabled after a predetermined time or number of races.

### BRIEF DESCRIPTION OF THE DRAWINGS

These and other features of the invention will now be described with reference to the drawings summarized below. These drawings and the associated description are provided to illustrate preferred embodiments of the invention and are not intended to limit the scope of the invention.

FIG. 1 illustrates local area networks (LANs) interconnected by an optical network.

FIG. 2 illustrates a top-level view of an interface to a network, where the interface includes transceivers.

FIG. 3 consists of FIGS. 3A and 3B and illustrates a transceiver according to one embodiment of the invention.

FIG. 4 illustrates one embodiment of a phase alignment circuit.

FIG. 5 illustrates one embodiment of a clock phase generator circuit shown in FIG. 4.

FIG. 6 is a timing diagram of the clock phase generator circuit.

FIG. 7 illustrates one embodiment of a multiplexer select circuit shown in FIG. 4.

FIG. 8 is a timing diagram of the multiplexer select circuit.

FIG. 9 illustrates one embodiment of a multiplexer shown in FIG. 4.

FIG. 10 is a timing diagram illustrating phase alignment of input data to a transmitter clock.

FIG. 11 illustrates one embodiment of a clock multiply unit.

FIG. 12 illustrates one embodiment of a phase frequency detector in the clock multiply unit.

FIG. 13 illustrates one embodiment of a phase frequency detector reset circuit shown in FIG. 12.

FIG. 14 is a timing diagram of the phase frequency detector of FIG. 12.

FIG. 15 is a circuit diagram of an enhanced Colpitts voltage controlled oscillator.

FIG. 16 is a circuit diagram of a coarse voltage tuning circuit.

FIG. 17 is a graph of frequency vs. voltage for a plurality of coarse/fine tuning curves for an enhanced Colpitts voltage controlled oscillator.

FIG. 18 is a block diagram of an implementation of a digital search filter for coarse tuning of an enhanced Colpitts voltage controlled oscillator.

FIG. 19 is a timing diagram of an automatic search mode of the digital search filter of FIG.18.

FIG. 20 is a timing diagram of a manual mode of the digital search filter of FIG. 18.

FIG. 21 is a flow chart of the decision logic of the implementation of the digital search filter of FIG. 18.

FIG. 22 is a schematic illustration of a high-speed output buffer.

### DETAILED DESCRIPTION OF PREFERRED EMBODIMENTS

Although this invention will be described in terms of certain preferred embodiments, other embodiments that are apparent to those of ordinary skill in the art, including embodiments which do not provide all of the benefits and features set forth herein, are also within the scope of this invention. Accordingly, the scope of the invention is defined only by reference to the appended claims.

Embodiments of the invention inexpensively and reliably communicate data at relatively high data rates. Embodiments of the invention include a receiver that receives relatively high-speed serial data and automatically demultiplexes the relatively high-speed serial data to a relatively low-speed parallel data. The receiver includes a phase locked loop that quickly and efficiently synchronizes a local voltage controlled oscillator to the relatively high-speed serial data. Embodiments of the invention also include a transmitter that receives relatively low-speed parallel data and automatically multiplexes the relatively low-speed parallel data to a relatively high-speed serial data.

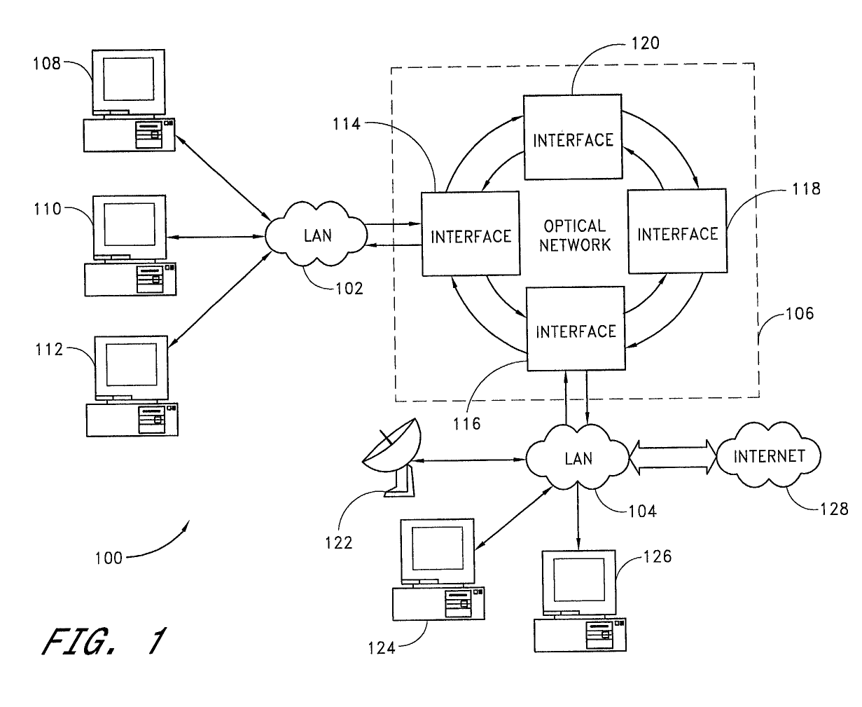

FIG. 1 illustrates a network 100 of interconnected computer systems. The illustrated network 100 includes a first local area network (LAN) 102, a second LAN 104, and an optical network 106. Computer systems 108, 110, 112 communicate with each other and external networks via the first LAN 102. The first LAN can correspond to a variety of network types, including electrical networks such as Ethernet and Fast Ethernet, and optical networks such as SONET Gigabit Ethernet 1000Base-SX and 1000Base-LX.

Networks of interconnected computer systems include transceivers. A transceiver is a device that both transmits and receives signals. A transceiver applies signals to a line in order to send data to other devices or circuits and also detects signals from a line to receive data from other devices or circuits.

The first LAN 102 communicates with the optical network 106 through a first interface 114. The optical network 106 shown in FIG. 1 is arranged in a ring. Of course, other topologies can be used such as point-to-point, star, hub, and the like. In one embodiment, the optical network 106 is a Synchronous Optical Network (SONET), and the first interface is an add/drop multiplexer (ADM). Another example of an optical network is a synchronous digital hierarchy (SDH). The interface 114 shown allows the first LAN 102 to download or drop data from and to upload or add data to the optical network 106, while allowing data unrelated to the first interface to continue or repeat to the other interfaces 116, 118, 120 in the optical network 106.

The second LAN 104 similarly communicates with the optical network 106 through a second interface 116. The optical network 106 can be either a LAN or a wide area network (WAN). The second LAN 104 shown allows a variety of devices to communicate with the optical network 106, such as a satellite dish 122, local computer systems 124, 126, and a connection to the Internet 128. In addition to computer data, the communication within the LANs 102, 104 and the optical network 106 can include a variety of data types including telephony data and video data.

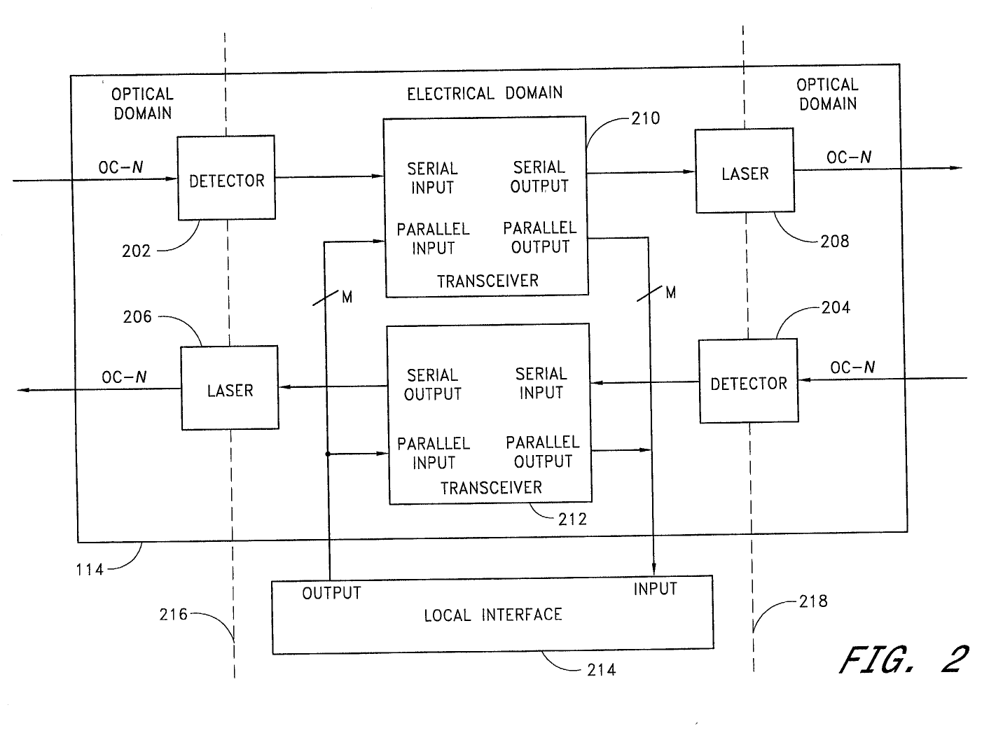

FIG. 2 illustrates further details of the first interface 114. The first interface 114 includes a first detector 202, a second detector 204, a first laser 206, a second laser 208, a first transceiver 210, a second transceiver 212, and a local interface 214. The first detector 202 and the first laser 206 allow the interface to communicate with a first path of an optical network. Similarly, the second detector 204 and the second laser 208 allow the interface to communicate with a second path of the optical network. Typically, the data in the optical network is modulated onto an optical carrier and carried within the network in fiber optic cables. The optical network can correspond to a variety of optical standards, such as numerous standards under SONET for optical carrier levels (OC) such as OC-1, OC-3, OC-12, OC-48, and OC-192, or more generally, OC-N.

The detectors 202, 204 receive the optical signals carried by the optical network and convert the optical signals to electrical signals, which are applied as inputs to the transceivers 210, 212. The lasers 204, 206 convert electrical signals from the transceivers 210, 212 to optical signals. Of course, the first interface 114 can further include conventional amplifiers, buffers, and the like. Dashed lines 216, 218 indicate where the signals are electrical and where the signals are optical.

The transceivers 210, 212 demultiplex the electrical signals from the detectors 202, 204. In one embodiment, the demultiplex process includes a conversion from serial data to parallel data. The transceivers 210, 212 drop data for the local system or local device associated with the interface 114 from the received signals and apply the extracted data as an input to the local interface 214. In addition, the transceivers 210, 212 add data from the local system or local device and combine the added data with the remainder of the received signals, i.e., the data that continues through the interface 114, and applies the combined data as inputs to the lasers 206, 208.

The illustrated embodiment of FIG. 2 uses the transceivers 210, 212 in an interface, such as an add/drop multiplexer (ADM). However, it will be understood by one of ordinary skill in the art that the transceivers can also be applied in other applications such as switches, digital cross connects, and test equipment.

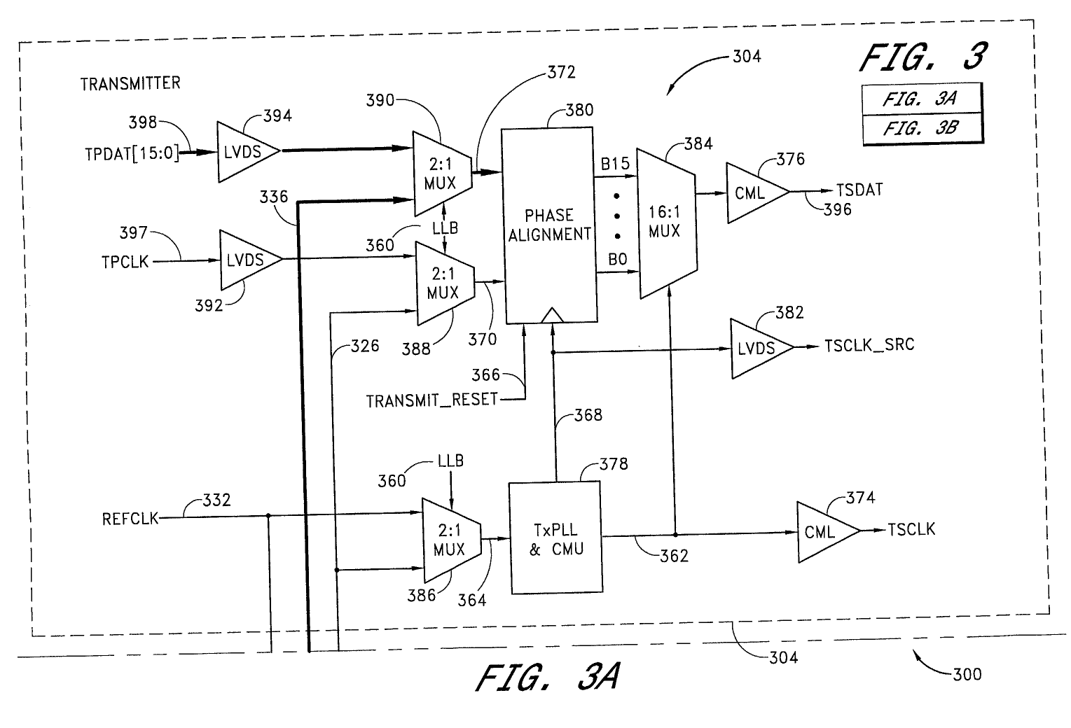

FIG. 3 illustrates a transceiver 300 according to one embodiment of the invention. Signals provided to, provided by, and internal to the transceiver 300 are differential signals. However, most signals in the illustration of FIG. 3 are shown as single lines for clarity. The transceiver 300 includes a receiver 302 and a transmitter 304. The receiver 302 accepts serial data 320 (RSDAT) at a receiver data input terminal 321, and the receiver 302 converts the serial data 320 to parallel data (RPDAT), which is available at a receiver data output terminal 344. For example, the receiver 302 of the transceiver 300 can receive the serial data 320 from the first detector 202 and can provide the parallel data (RPDAT) to the local interface 214.

The transmitter 304 accepts parallel data (TPDAT) at a transmitter data input terminal 398, and the transmitter 304 converts the parallel data (TPDAT) to serial data (TSDAT), which is available at a transmitter data output terminal 396. For example, the transmitter 304 can receive parallel data (TPDAT) from an output of the local interface 214 and can provide the converted serial data (TSDAT) as an input to the second laser 208. The transmitter 304 also receives a data clock (TPCLK) and a reference clock (REFCLK) which can come from the local interface 214. In addition to providing the serial data (TSDAT), the transmitter 304 provides an associated transmit clock (TSCLK) which can be sent in parallel with the serial data to a destination device. The transmitter 304 also outputs a sub-multiple of the transmit clock (TSCLK_SRC) which can be used for testing purposes or provided to the local interface 214.

In one embodiment, the transceiver 300 is implemented by silicon-germanium (Si—Ge) npn bipolar transistors. However, it will be understood by one of ordinary skill in the art that the circuits can also be implemented with other technologies, such as Si—Ge pnp bipolar transistors, silicon npn or pnp bipolar transistors, metal-oxide semiconductor field-effect transistors (MOSFETs), gallium arsenide metal semiconductor field-effect transistors (GaAs FETs or MESFETs), heterojunction bipolar transistors (HBTs), Si—Ge bipolar complementary metal-oxide semiconductor (BiCMOS), and the like. In one embodiment of the transceiver 300, the transistors operate substantially in the linear region and do not reach cutoff or saturation under normal operating conditions.

The illustrated transceiver 300 couples to power and to ground through V_{DD} and Vₛₛ, respectively. It will be understood by one of ordinary skill in the art that the voltage provided to the transceiver 300 by a power supply can vary widely from application to application, and the transceiver 300 can be designed to accommodate a relatively wide range of voltage. In one embodiment, V_{DD} is about 3.3 Volts relative to Vₛₛ. Preferably, V_{DD} is maintained to about ±10% of 3.3 Volts relative to V_{SS}. More preferably, V_{DD} is within about ±5% of 3.3 Volts relative to V_{SS}.

The illustrated receiver 302 includes a receiver phase locked loop (Rx PLL) and clock data recovery (CDR) circuit 306, an acquisition aid circuit 308, a demultiplexer circuit 310, a framer circuit 312, an output register circuit 314, and low voltage differential signaling (LVDS) drivers 316, 318.

The Rx PLL and CDR circuit 306 is coupled to the receiver data input terminal 320 to receive the serial data 320 (RSDAT), and extracts a receiver clock signal 326 (VCO_16) from the serial data 320 (RSDAT). The receiver clock signal (VCO_16) 326 is applied as an input to other circuits in the receiver 302. In one embodiment, the receiver clock signal 326 (VCO_16) is supplied as an output to the system through the LVDS driver 316. One embodiment of the Rx PLL and CDR circuit 306 also at least partially demultiplexes the serial data 320 (RSDAT) to a partially demultiplexed data 324 while the Rx PLL and CDR circuit 306 recovers the clock signal. In one embodiment, the partially demultiplexed data 324 is an 8-bit wide data path.

The acquisition aid circuit 308 receives a reference clock signal 332 from an external source and receives the receiver clock signal 326 from the RX PLL and CDR circuit 306. The reference clock signal 332 is derived from a relatively stable source such as a quartz oscillator. When the receiver clock signal 326 is properly detected by the Rx PLL and CDR circuit 306, the receiver clock signal 326 is closely related to the reference clock signal 332. In one example, the receiver clock signal 326 is closely related to the reference clock signal 332 in frequency but not in phase. In one example, when properly detected, the receiver clock signal 326 is within a predetermined variance from the reference clock signal 332. It will be understood by one of ordinary skill in the art that the frequencies of the receiver clock signal 326 and the reference clock signal 332 can also be related to each other through a multiple or sub-multiple.

The acquisition aid circuit 308 compares the relative frequencies of the reference clock signal 332 and the receiver clock signal 326. The acquisition aid circuit 308 activates an AA signal 328 in response to a detection of a relatively close match in frequency between the reference clock signal 332 and the receiver clock signal 326. The AA signal 328 is used to indicate whether the Rx PLL and CDR 306 circuit has properly detected the receiver clock signal 326 (VCO_16). A receiver lock detected signal 330 (RLOCKDET), which derives from the AA signal 328, provides a feedback indication to the Rx PLL and CDR circuit 306 that it is properly detecting the receiver clock signal 326. When the receiver clock signal 326 (VCO_16) drifts from the reference clock signal 332 (REFCLK) by at least a predetermined amount, a phase locked loop within the Rx PLL and CDR circuit 306 locks to the reference clock signal 332 (REFCLK), rather than to the receiver serial data 320 (RSDAT), to maintain the frequency of the phase locked loop to within a lock range of the phase locked loop for a properly detected receiver clock signal 326.

The demultiplexer circuit 310 receives the partially demultiplexed data 324 and the receiver clock signal 326 as inputs from the Rx PLL and CDR circuit 306. The demultiplexer circuit 310 converts the partially demultiplexed data 324 to a fully demultiplexed data 338 and applies the fully demultiplexed data 338 as an input to the framer 312. In one embodiment, the fully demultiplexed data 338 path is 16-bits wide.

The framer circuit 312 receives the fully demultiplexed data 338 from the demultiplexer circuit 310 and uses the frame headers within the data to align the data in accordance with a predetermined standard, such as the SONET standard. The framer circuit 312 also performs data integrity checking operations such as parity checking and run length limited operations, and the framer circuit 312 extracts the raw data and the frame header components from the fully demultiplexed data 338.

The output register 314 receives the aligned data 340 from the framer circuit 312, synchronizes the aligned data 340 and other signals to the receiver clock. Synchronized aligned data 336 (POUT[15:0]) is applied as inputs to the LVDS drivers 318 and sent to an external receiving device, such as an add/drop multiplexer (ADM). In addition, the output register 314 receives an FP signal 342 and a parity error signal 334, and aligns the signals to an FPOUT signal 348 and a parity output signal (PAROUT) signal 354, respectively. The FPOUT signal 348 is further buffered by a LVDS buffer 317 to a differential FPOUTD signal, which is supplied externally to indicate that the receiver 302 has detected a transition between framing bytes. The parity output signal 334 indicates that the data provided by the receiver 300 is corrupted.

The illustrated transmitter 304 includes LVDS input buffers 392, 394, multiplexers 384, 386, 388, 390, a phase alignment circuit 380, a clock multiply unit 378, a LVDS output driver 382, and current mode logic (CML) drivers 374, 376.

Parallel input data (e.g., 16-bits wide words TPDAT[15:0]) is provided to a transmitter data input terminal 398 which is coupled to input terminals of the LVDS buffers 394. In one embodiment, the LVDS input buffers 394 are a set of 16 LVDS input buffers coupled to the respective bits of the parallel input data. A data clock (TPCLK) associated with the parallel input data is provided to a data clock input terminal 397 which is coupled to an input terminal of the LVDS buffer 392. The LVDS input buffers 392, 294 strengthen signals, such as the parallel input data and its associated clock, which may have traveled in lossy lines, have been subjected to noisy environments, or have been provided to multiple devices in parallel.

The outputs of the LVDS input buffers 394 are provided to inputs of the multiplexers 390. In one embodiment, the multiplexers 390 are a set of 16 2:1 multiplexers coupled to the respective outputs of the LVDS input buffers 394. Data lines 336 from the receiver 302 are also coupled to the multiplexers 390. The outputs of the multiplexers 390 are provided to the phase alignment circuit 380 via data lines 372.

During normal operation, the multiplexers 390 select the parallel input data from the transmitter data input terminal 398 to output on the data lines 372 for processing by the transmitter 304. During a test mode (i.e. a low-frequency loop back test), the multiplexers 390 select data on the data lines 336 from the receiver 302 to output on the data lines 372. A line loop back (LLB) signal 360 is provided to the multiplexers 390 to perform the data selection. The low-frequency loop back test is further described below.

The output of the LVDS input buffer 392 is provided to an input of the 2:1 multiplexer 388. A clock signal on a receiver clock signal line 326 is provided to another input of the multiplexer 388. The output of the multiplexer 388 is provided to the phase alignment circuit 380 via an input clock line 370.

During normal operation, the multiplexer 388 selects the data clock (TPCLK) at the data clock input terminal 397 of the transmitter 304 to output on the input clock line 370. During the low-frequency loop back test, the multiplexer 388 selects the clock signal on the receiver clock signal line 326 to output on the input clock line 370. The LLB signal 360 is provided to the multiplexer 388 to perform the clock selection. The low-frequency loop back test is further described below.

A reference clock (REFCLK) is provided to an input terminal of the 2:1 multiplexer 386 via a transmitter input terminal 332. The clock signal on the receiver clock signal line 326 is provided to another input of the multiplexer 386. The output of the multiplexer 386 is provided to the clock multiply unit 378 via a reference clock line 364.

During normal operation, the multiplexer 386 selects the reference clock (REFCLK) at the input terminal 332 of the transmitter 304 to output on the reference clock line 364. During the low-frequency loop back test, the multiplexcer 386 selects the clock signal on the receiver clock signal line 326 to output on the reference clock line 364. The LLB signal 360 is provided to the multiplexer 388 to perform the reference clock selection. The low-frequency loop back test is further described below.

The clock multiply unit (CMU) 378 receives a reference clock signal on the reference clock line 364 and generates transmitter clocks which are phase locked with the reference clock signal. The outputs of the CMU 378 (i.e., transmitter clocks) are provided to other circuits in the transmitter 304, such as the phase alignment circuit 380, the multiplexer 384, and the CML output driver 374. The frequencies of transmitter clocks can be sub-multiples or multiples of the reference clock signal. In one embodiment, the reference clock signal is approximately 622 MHz, a first output of the CMU 378 (i.e., a first transmitter clock) provided to the phase alignment circuit 380 via clock line 368 is substantially the same frequency while a second output of the CMU 378 (i.e., a second transmitter clock) provided to the multiplexer 384 and the CML driver 374 via clock line 362 is approximately 10 GHz (i.e., approximately 16 times the frequency of the reference clock signal). The CMU 378 is explained in more detail below.

In addition to receiving the first transmitter clock via the clock line 368, the phase alignment circuit 380 receives a transmitter reset signal (TRANSMIT_RESET) on signal line 366, the data signals on data lines 372, and the associated data clock on input clock line 370. The phase alignment circuit 380 aligns the phases of the data signals to the phases of the first transmitter clock and provides the aligned data to the 16:1 multiplexer 384 for conversion to a serial format using the second transmitter clock which is phase locked with the first transmitter clock. The frequency of the second transmitter clock is a multiple of the frequency of the first transmitter clock. The phase alignment circuit 380 is explained in more detail below.

The serial output of the 16:1 multiplexer 384 is provided to the CML driver 376. The output of the CML driver 376 is coupled to the transmitter data output terminal 396 to provide the serial data (TSDAT). The first transmitter clock is provided to the LVDS driver 382 which outputs a clock signal (TSCLK_SRC) with a frequency that is a sub-multiple of the transmission frequency. The second transmitter clock is provided to the CML driver 374 which outputs a clock signal (TSCLK) with a frequency that is substantially the same as the transmission frequency.

One embodiment of the transceiver 300 further includes a low-frequency loop back path. The low-frequency loop back path advantageously allows a relatively thorough test of the related lasers, fiber optic cables, optical detectors, and transceivers and yet, provides test equipment with a relatively simple interface.

By contrast, a line test disadvantageously fails to test a significant portion of a transceiver 300. For example, in a line test, test equipment applies test data serially to the receiver data input terminal 320, the transceiver 300 couples the receiver data input terminal 320 to the transmitter data output terminal 396, and the test equipment reads the test data from the transmitter data output terminal 396 to complete the test. Disadvantageously, potential malfunctions within the transceiver 300 can go undetected in a simple line test.

In another test known as a diagnostic test, test equipment applies test data to the low-frequency side of a transceiver 300 through a transmitter data input terminal 398. The test data propagates through circuits in a transmitter 304 of the transceiver 300 to a transmitter data output terminal 396, is coupled from the transmitter data output terminal 396 to a receiver data input terminal 320, and propagates through circuits in a receiver 302 of the transceiver 300 to a receiver data output terminal 344, where the test data is read by the test equipment to complete the test. Although the diagnostic test tests a relatively large portion of the transceiver 300, implementation of the diagnostic test disadvantageously requires a relatively large array of relatively expensive test equipment.

A low-frequency loop back advantageously allows a new test combining the relative thorough testing associated with the diagnostic test with the ease and simplicity of the line test. With reference to FIG. 3, test equipment activates a line loop back (LLB) signal 360 to prepare a transceiver 300 for the low-frequency loop back test. The LLB signal 360 is applied to select input terminals of respective multiplexers 386, 388, 390 in a transmitter of the transceiver 300. In one embodiment, the test equipment applies test data in a serial format to a receiver 302 at a receiver data input terminal 320. The test data is converted to a parallel format by the receiver 302, is coupled from an output stage of the receiver 302 to an input stage of the transmitter 304 in the parallel format, is converted back to the serial format by the transmitter 304, and is provided in the serial format at a transmitter data output terminal 396 for reading by the test equipment.

During the low-frequency loop back test, a clock signal associated with the test data is also coupled from the receiver 302 to the transmitter 304. The coupling of the test data and the associated clock signal from the receiver 302 to the transmitter 304 is achieved by the LLB signal 360. In response to the activation of the LLB signal 360, the set of data multiplexers 390 in the transmitter 304 selects data on data lines 336 from an output stage of the receiver 302 (e.g., data at inputs of LVDS drivers 318) for processing by the transmitter 304. In response to the activation of the LLB signal 360, the data clock multiplexer 388 selects a clock signal on a receiver clock signal line 326 (VCO_16) as an input to a phase alignment circuit 380 of the transmitter 304. In response to the activation of the LLB signal 360, the reference clock multiplexer 386 also selects the clock signal on the receiver clock signal line 326 (VCO_16) as an input to a clock multiply unit 378 of the transmitter 304.

As described above, the test data is applied serially to the receiver data input terminal 320, the test data propagates through a portion of the receiver 302 to a low-frequency or parallel side of the receiver 302, and the receiver 302 provides the test data in parallel form through the data lines 336. The receiver 302 also recovers embedded clock information in the test data and provides at least a portion of the recovered clock signal to the transmitter 304 as illustrated by the receiver clock signal line 326.

The transmitter 304 portion of the transceiver 302 receives the parallel test data on data lines 336 and the clock signal on the receiver clock signal line 326, and the transmitter 304 generates a serial bitstream from the parallel test data as an output at the transmitter data output terminal 396, which is applied as an input to and read by the test equipment. Advantageously, the illustrated low-frequency loop back allows testing of a substantial portion of the transceiver 300 from the high-speed serial interface side of the transceiver 300, thereby obviating the need for expensive and complex test equipment.

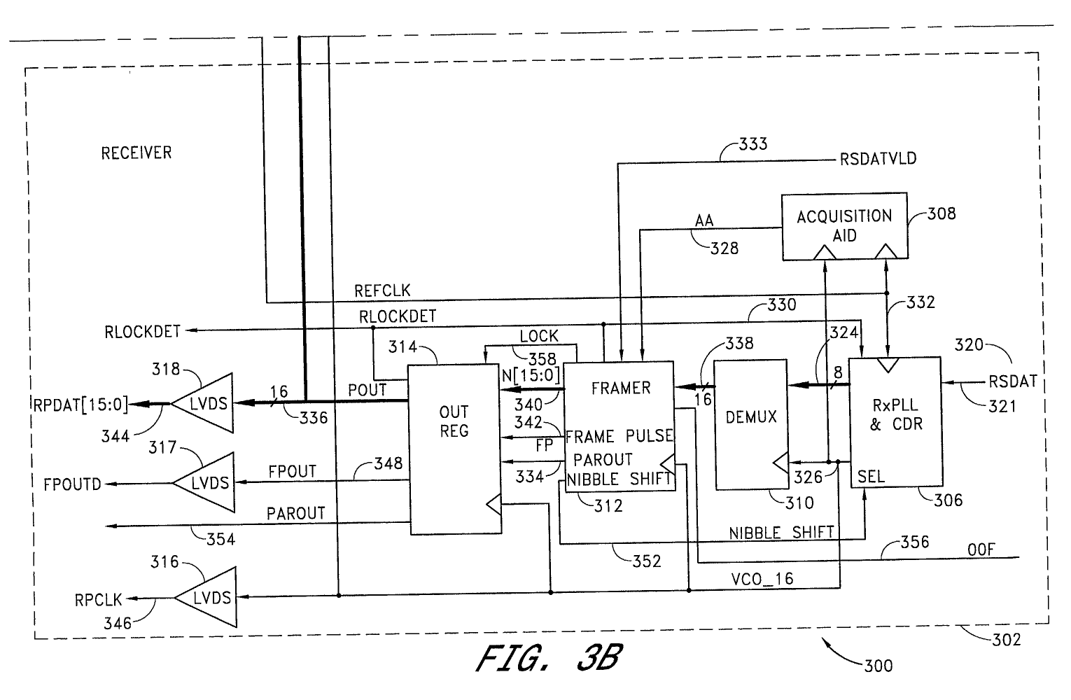

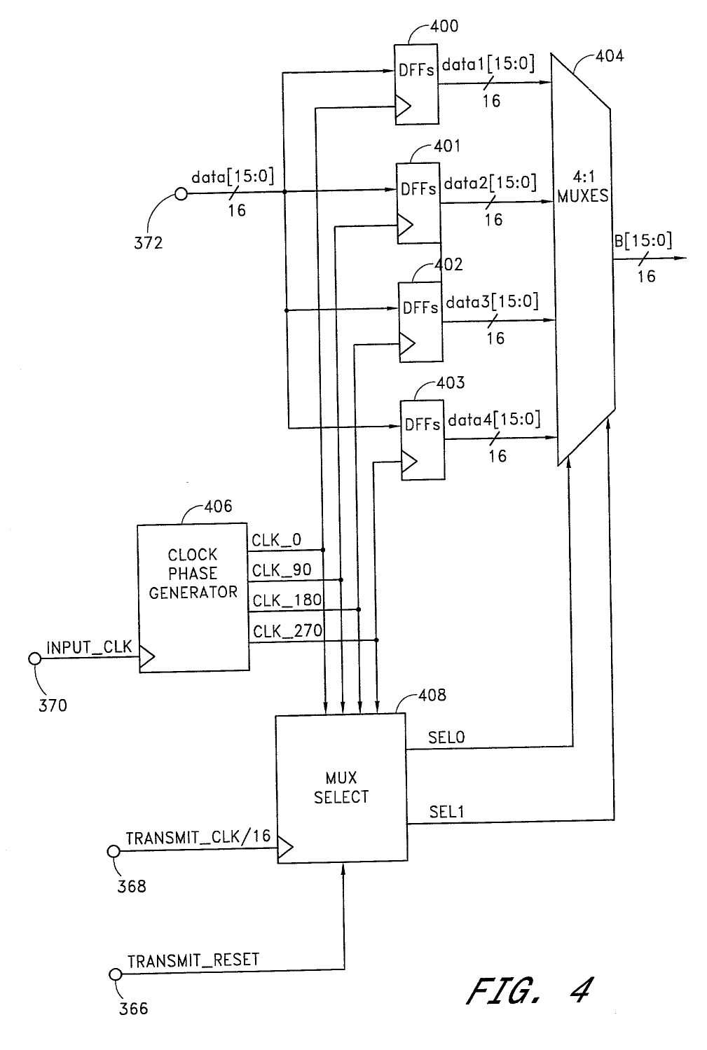

FIG. 4 illustrates one embodiment of a phase alignment circuit 380 which aligns an input data stream (data[15:0]) to a transmission clock (transmit_clk/16) in the transmitter 304. The illustrated phase alignment circuit 380 includes four sets of D-type flip-flops (DFFs) 400, 401, 402, 403, a set of 4:1 multiplexers 404, a clock phase generator 406, and a multiplexer select circuit 408. As discussed above, signals internal to the transceiver are differential signals (i.e., each signal is represented by a difference between two signal lines). For clarity, the signals in FIG. 4 are shown coupled to single lines.

An input clock (input_clk) on an input clock line 370 is provided to an input of the clock phase generator 406. In one embodiment, the input clock is a data clock (TPCLK) which is sent with parallel input data (TPDAT[15:0]) to the transmitter 304, and the data clock is synchronous with the parallel input data. The clock phase generator generates a plurality of multi-phase clocks with a common speed and multiple phases. The common speed is a sub-multiple of the input clock. For example, the clock phase generator 406 outputs four substantially equivalent speed clock signals (clk_0, clk_90, clk_180, clk_270) with 90 degrees offsets, phase locked to the input clock and with speeds approximately a quarter of the speed of the input clock. During normal operation, the input clock is the data clock (TPCLK) at the data clock input terminal 397 of the transmitter 304. During a test mode, the input clock is the clock signal on the receiver clock signal line 326. The clock phase generator 406 is described in further detail below.

The zero degree clock signal (clk_0) at the output of the clock phase generator 406 is provided to clock inputs of the first set of DFFs 400. The 90 degrees clock signal (clk_90) at the output of the clock phase generator 406 is provided to clock inputs of the second set of DFFs 401. The 180 degrees clock signal (clk_180) at the output of the clock phase generator 406 is provided to clock inputs of the third set of DFFs 400. The 270 degrees clock signal (clk_270) at the output of the clock phase generator 406 is provided to clock inputs of the fourth set of DFFs 400.

In one embodiment, each of the four sets of DFFs 400, 401, 402, 403 includes 16 DFFs. Parallel input data (data[15:0]) on data lines 372 is provided in parallel to data inputs of the four sets of DFFs 400, 401, 402, 403 (e.g., data[0] is provided to inputs of first DFFs in each set of DFFs, data[1] is provided to inputs of second DFFs in each set of DFFs, etc.).

The four clock signals (clk_0, clk_90, clk_180, clk_270) at the clock inputs of the respective sets of DFFs 400, 401, 402, 403 are a quarter speed of the data inputs. The four sets of DFFs 400, 401, 402, 403 effectively demultiplex the input data (data[15:0]) into four sets of parallel data (or intermediate data streams) at 90 degrees offsets which are a quarter speed of the input data.

The first set of DFFs 400 outputs a first set of quarter-speed parallel data (data1[15:0]) at zero degrees to first inputs of the set of multiplexers 404. The second set of DFFs 401 outputs a second set of quarter-speed parallel data (data2[15:0]) at 90 degrees to second inputs of the set of multiplexers 404. The third set of DFFs 400 outputs a third set of quarter-speed parallel data (data3[15:0]) at 180 degrees to third inputs of the set of multiplexers 404. The fourth set of DFFs 400 outputs a fourth set of quarter-speed parallel data (data4[15:0]) at 270 degrees to fourth inputs of the set of multiplexers 404.

Base on sequence signals (i.e., select signals) (se10, se11) from the multiplexer select circuit 408 explained in farther detail below, the set of multiplexers 404 (i.e., 16 4:1 multiplexers) combines the four sets of quarter-speed parallel data back into one set of output parallel data (B[15:0]) with substantially the same speed as the speed of the input data (data[15:0]). However, the output parallel data (B[15:0]) is phase locked to a first transmitter clock (transmit_clk/16) on clock line 368 while the input data (data[15:0]) is phase locked to the input clock (input_clk) on input clock line 370. In one embodiment, the input clock is a relatively noisy clock that is sent to the transmitter with the parallel input data, and the first transmitter clock is a relatively quiet clock that is generated by the transmitter from a reference clock.

The first transmitter clock (transmit_clk/16) on clock line 368 is provided to a clock input of the multiplexer select circuit 408. A transmitter reset signal (TRANSMIT_RESET) is also provided on a signal line 366 to an input of the multiplexer select circuit 408. The transmitter reset signal can come from the local interface 214, the network, or generated by the transceiver 300. The quarter-speed clocks (clk_0, clk_90, clk_180, clk_270) from the clock phase generator 406 are also provided to the multiplexer select circuit 408. The multiplexer select circuit 408 generates the select signals (se10, se11) which are provided to the set of 4:1 multiplexers 404 to control the sequencing of data. The select signals (se10, se11) are phased locked to the first transmitter clock (transmit_clk/16). The transmitter reset signal (TRANSMIT_RESET) and the quarter-speed clocks (clk_0, clk_90, clk_180, clk_270) initializes the select signals (se10, se11) to avoid collisions between transitions of data in the quarter-speed parallel data and transitions of corresponding data in the output parallel data (B[15:0]). The multiplexer select circuit is discussed in further detail below.

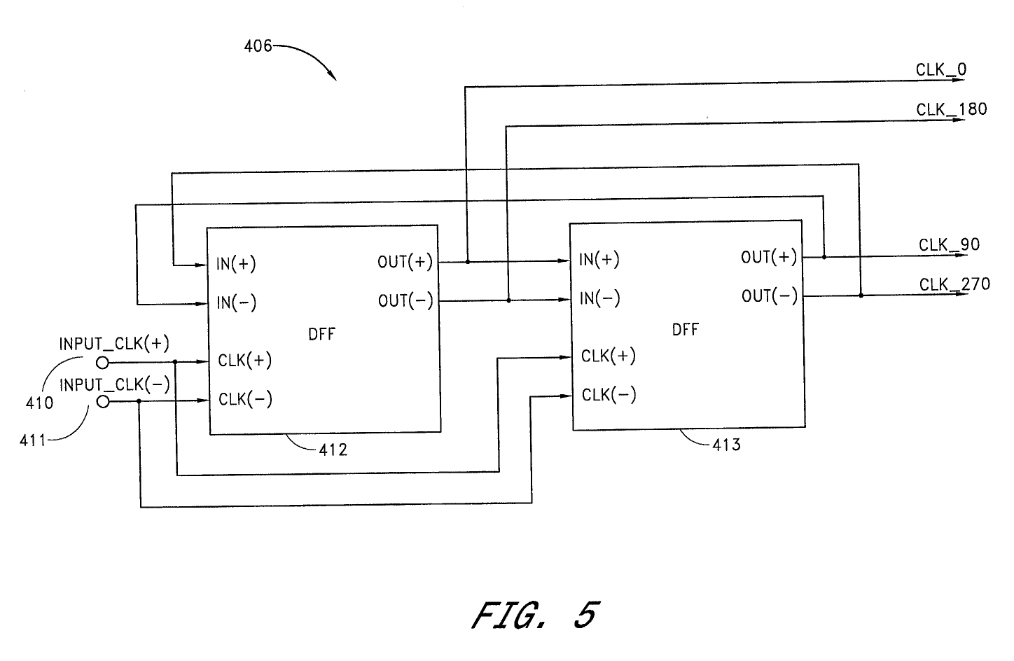

FIG. 5 illustrates one embodiment of a clock phase generator circuit 406 shown in FIG. 4. The clock phase generator circuit 406 includes two interconnected D-type flip-flops (DFFs) 412, 413. Differential outputs (out(+), out(−)) of the first DFF 412 is provided to respective differential inputs (in(+), in(−)) of the second DFF 413. Differential outputs (out(+), out(−)) of the second DFF 413 is provided in reversed order to respective differential inputs (in(+), in(−)) of the first DFF 412, i.e., the positive output (out(+)) of the second DFF 413 is provided to the negative input (in(−)) of the first DFF 412 and the negative output (out(−)) of the second DFF 413 is provided to the positive input (in(+)) of the first DFF 412.

Differential input clocks (input_clk(+), input_clk(−)) on respective clock lines 410, 411 are provided to differential clock inputs (clk(+), clk(−)) of both the DFFs 412, 413. The clock lines 410, 411 are a differential version of the clock line 370 shown in FIG. 4. The clock phase generator 406 outputs four substantially equivalent speed clock signals (clk_0, clk_90, clk_180, clk_270) with 90 degrees offsets, phase locked to the input clock and with speeds approximately a quarter of the speed of the input clock. For example, the positive output of the first DFF 412 is the zero degrees clock signal (clk_0), the negative output of the first DFF 412 is the 180 degrees clock signal (clk_180), the positive output of the second DFF 413 is the 90 degrees clock signal (clk_90), and the negative output of the second DFF 413 is the 270 degrees clock signal (clk_270).

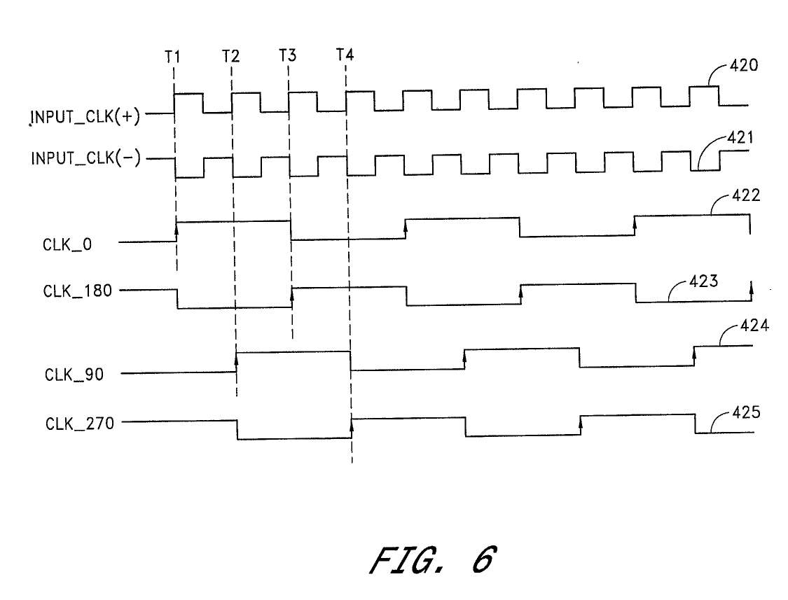

FIG. 6 is a timing diagram of the clock phase generator circuit 406 illustrated in FIG. 5. A graph 420 represents the positive input clock (input_clk(+)) as a function of time. A graph 421 represents the negative input clock (input_clk(−)) as a function of time. A graph 422 represents the zero degrees clock signal (clk_0) as a function of time. A graph 423 represents the 180 degrees clock signal (clk_180) as a function of time. A graph 424 represents the 90 degrees clock signal (clk_90) as a function of time. A graph 425 represents the 270 degrees clock signal (clk_270) as a function of time.

In one embodiment, the positive input clock (input_clk(+)) and its opposite polarity, the negative input clock (input_clk(−)), are approximately 622 MHz clock signals. The clock signals (clk_0, clk_90) are quarter speed clocks (i.e., approximately 155 MHz) which are 90 degrees offset from each other. The clock signals (clk_180, clk_270) are opposite polarity of the respective clock signals (clk_0, clk_90).

The quarter-speed clock signals (clk_0, clk_90, clk_180, clk_270) are phased locked to the positive input clock (input_clk(+)). For example, after the clock phase generator circuit 406 resets, the quarter-speed clock signal (clk_0) transitions to logic high at the first rising edge (T1) of the positive input clock (input_clk(+)), the quarter-speed clock signal (clk_90) transitions to logic high at the second rising edge (T2) of the positive input clock (input_clk(+)), the quarter-speed clock signal (clk_180) transitions to logic high at the third rising edge (T3) of the positive input clock (input_clk(+)), and the quarter-speed clock signal (clk_270) transitions to logic high at the fourth rising edge (T4) of the positive input clock (input_clk(+)).

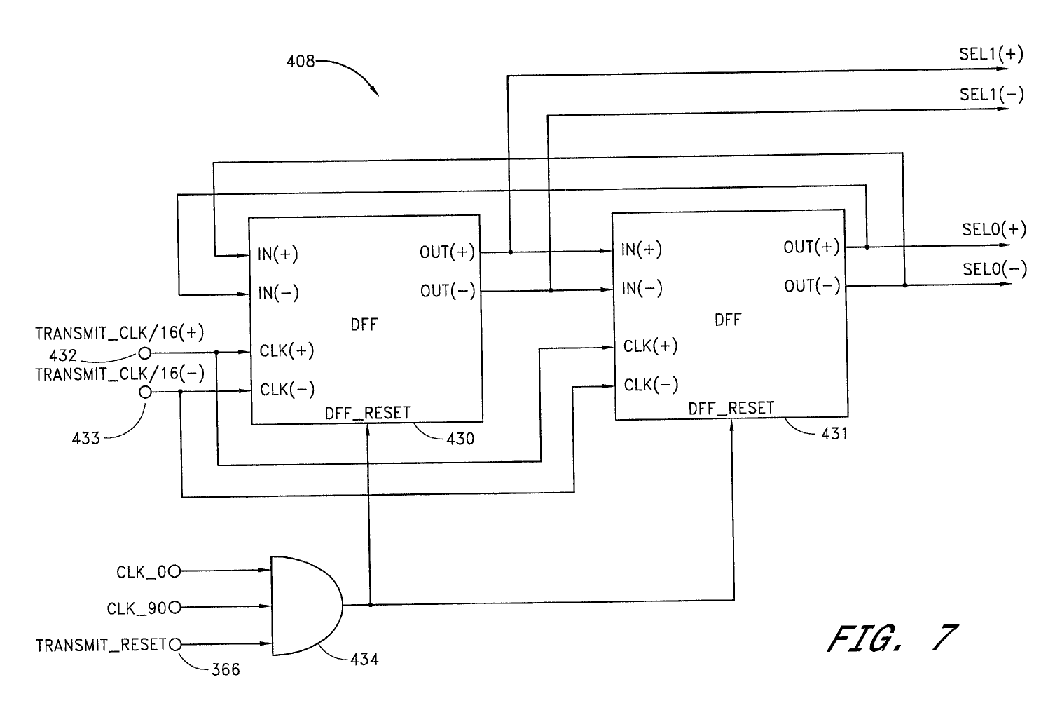

FIG. 7 illustrates one embodiment of a multiplexer select circuit 408 shown in FIG. 4. The multiplexer select circuit 408 includes a logic circuit (i.e., logic gate) 434 and two interconnected D-type flip-flops (DFFS) 430, 431. Differential outputs (out(+), out(−)) of the first DFF 430 is provided to respective differential inputs (in(+), in(−)) of the second DFF 431. Differential outputs (out(+), out(−)) of the second DFF 431 is provided in reversed order to respective differential inputs (in(+), in(−)) of the first DFF 430, i.e., the positive output (out(+)) of the second DFF 431 is provided to the negative input (in(−)) of the first DFF 430 and the negative output (out(−)) of the second DFF 431 is provided to the positive input (in(+)) of the first DFF 412.

Differential transmitter clocks (transmit_clk/16(+), transmit_clk/16(−)) on respective clock lines 432, 433 are provided to differential clock inputs (clk(+), clk(−)) of both the DFFs 430, 431. The clock lines 432, 433 are a differential version of the clock line 368 shown in FIG. 4. The multiplexer select circuit 408 outputs two pairs of differential select signals (se10(+/−), se11(+/−)) with 90 degrees offsets, phase locked to the transmitter clock and with speeds approximately a quarter of the speed of the transmitter clock.

A transmitter reset signal (TRANSMIT_RESET) on signal line 366 and clock signals (clk_0, clk_90) from the clock phase generator 406 are provided to inputs of the logic gate 434. The output of the logic gate is coupled to reset inputs (DFF_Reset) of the DFFs 430, 431. In one embodiment, the logic gate 434 is an AND gate. Therefore, when the transmitter reset signal (TRANSMIT_RESET) and the clock signals (clk_0, clk_90) are logic high, the outputs of the DFFs 430, 431 reset.

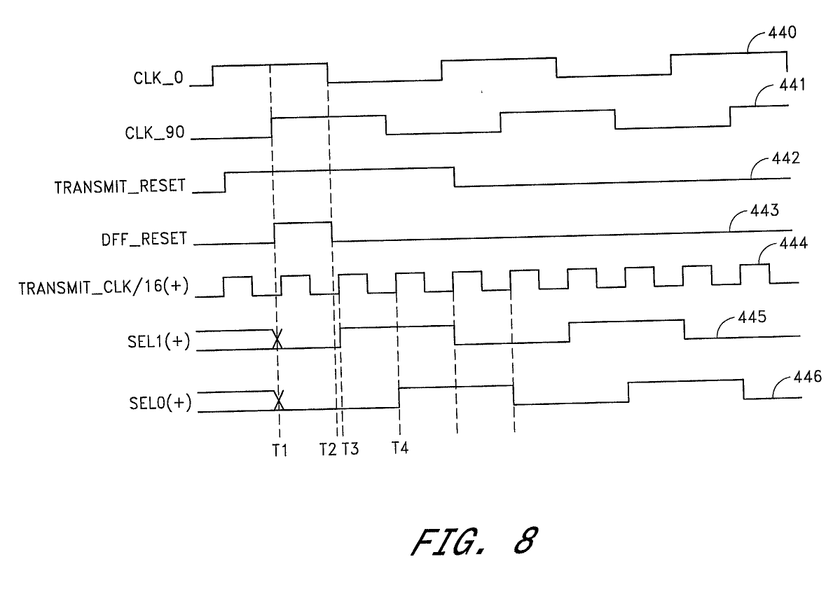

FIG. 8 is a timing diagram of the multiplexer select circuit 408 shown in FIG. 7. For clarity, only positive portions of differential signals are represented. A graph 440 represents a zero degree clock signal (clk_0) from an output of the clock phase generator 406 shown in FIG. 4. A graph 441 represents a 90 degrees clock signal (clk_90) from another output of the clock phase generator 406. A graph 442 represents a transmitter reset signal (TRANSMIT_RESET) which can be provided by the local interface 214, the network, or the transceiver 300. A graph 443 represents a DFF reset signal (DFF_Reset) which resets DFFs 430, 431 in the multiplexer select circuit 408. A graph 444 represents a transmitter clock (transmit_clk/16(+)). A graph 445 represents one of the select signals (se11(+)) outputted by the multiplexer select circuit 408. A graph 446 represents another of the select signals (se10(+)) outputted by the multiplexer select circuit 408.

In one embodiment, the transmitter clock (transmit_clk/16(+)) is approximately 622 MHz. The zero degree clock signal (clk_0) and the 90 degrees clock signal (clk_90) are approximately a quarter of the speed of the transmitter clock (i.e., approximately 155 MHz) and are not necessarily phased locked to the transmitter clock.

The transmitter reset signal (TRANSMIT_RESET) is a non-periodic signal which is active during power up, initialization, or other resetting condition of the transmitter 304. The transmitter reset signal is active for a length of time approximately equivalent to one period of the zero degree clock signal or the 90 degrees clock signal. In one embodiment, the outputs of the multiplexer select circuit 408 reset when the transmitter reset signal is active and both the zero degree clock signal and the 90 degrees clock signal are logic high. Other combinations of the clock signals (clk_0, clk_90) can be used to reset the multiplexer select circuit 408.

In the embodiment illustrated by FIG. 8, the DFF reset signal (DFF_Reset) is active (i.e., logic high) when the transmitter reset signal (TRANSMIT_RESET), the zero degree clock signal (clk_0), and the 90 degrees clock signal (clk_90) are active. The DFF reset signal resets the DFFs 430, 431 in the multiplexer select circuit 408, thereby resetting the select outputs of the multiplexer select circuit 408. For example, the select outputs (se11(+), se10(+)) are logic low from time T1 to time T2 corresponding to the logic high of the DFF reset signal.

The DFF reset signal effectively resets and initializes the select outputs of the multiplexer select circuit 408. The select outputs of the multiplexer select circuit 408 are phase locked to the transmitter clock (transmit_clk/16(+)) but run at a quarter of the speed of the transmitter clock. Furthermore, the two pairs of differential select outputs are offset by 90 degrees from each other. For example, at time T3 corresponding to the first rising edge of the transmitter clock (transmit_clk/16(+)) after reset of the select outputs, one of the select outputs (se11(+)) transitions from logic low to logic high. Then at time T4 corresponding to the second rising edge of the transmitter clock after reset of the select outputs, another of the select outputs (se10(+)) transitions from logic low to logic high.

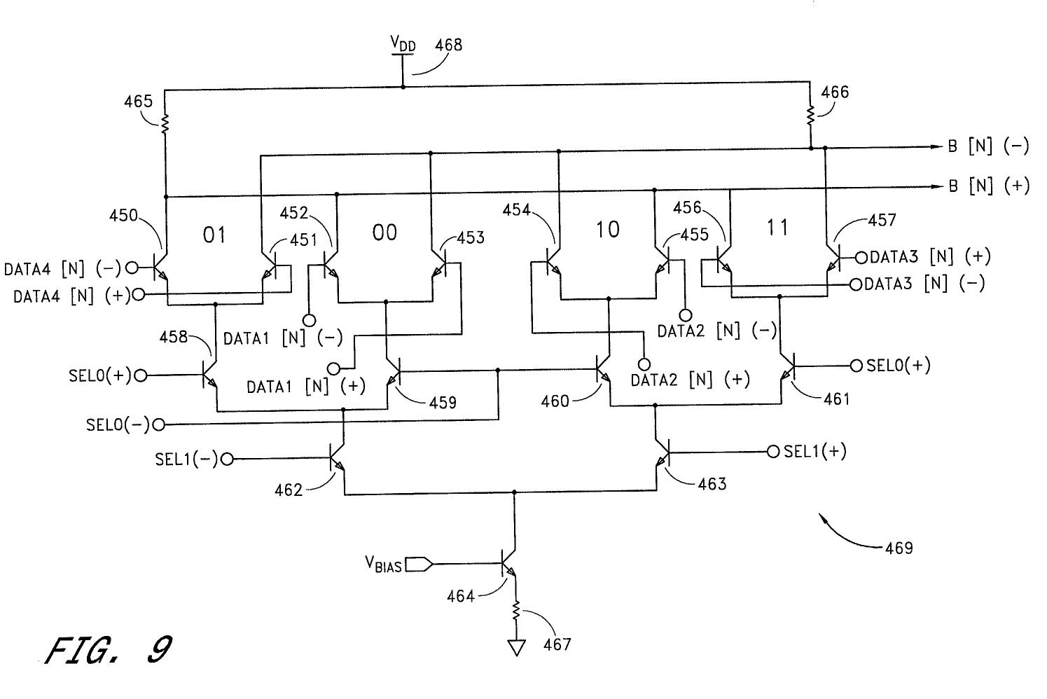

FIG. 9 illustrates one embodiment of a portion of the multiplexers 404 shown in FIG. 4. The multiplexers 404 are a set of 4:1 multiplexers. In one embodiment, the set of multiplexers 404 includes 16 4:1 multiplexers corresponding to 16 bits of the input data (data[15:0]). FIG. 9 illustrates one of the 4:1 multiplexers 469. The 4:1 multiplexer 469 includes seven pairs of differential pair transistors discussed in further detail below, a first resistor 465 coupled between a positive output (B[n](+)) of the 4:1 multiplexer 469 and a power supply terminal (VDD) 468, a second resistor 466 coupled between a negative output (B[n](−)) of the 4:1 multiplexer 469 and VDD 468, a bias transistor 464, and a third resistor 467 coupled between the emitter terminal of the bias transistor 464 and ground.

A bias voltage (Vbias) is provided to the base terminal of the bias transistor 464 to control current flow through the bias transistor 464. The collector terminal of the bias transistor 464 is coupled to the common emitter terminals of the first differential pair transistors 462, 463. A pair of differential select signals (sell(+/−)) is provided to the base terminals of the respective transistors 463, 462. The collector terminal of the transistor 462 is coupled to the common emitter terminals of the second differential pair transistors 458, 459. A pair of differential select signals (se10(+/−)) is provided to the base terminals of the respective transistors 458, 459. The collector terminal of the transistor 463 is coupled to the common emitter terminals of the third differential pair transistors 460, 461. The pair of differential select signals (se10(+/−)) is provided to the base terminals of the respective transistors 461, 460.

The collector terminal of the transistor 458 is coupled to the common emitter terminals of the fourth differential pair transistors 450, 451. A pair of differential data signals (data4[n](+/−)) is provided to the base terminals of the respective transistors 451, 450. The collector terminals of the transistors 450, 451 are coupled to the respective outputs (B[n](+/−)) of the 4:1 multiplexer 469.

The collector terminal of the transistor 459 is coupled to the common emitter terminals of the fifth differential pair transistors 452, 453. A pair of differential data signals (data1 [n](+/−)) is provided to the base terminals of the respective transistors 453, 452. The collector terminals of the transistors 452, 453 are coupled to the respective outputs (B[n](+/−)) of the 4:1 multiplexer 469.

The collector terminal of the transistor 460 is coupled to the common emitter terminals of the sixth differential pair transistors 454, 455. A pair of differential data signals (data2[n](+/−)) is provided to the base terminals of the respective transistors 454, 455. The collector terminals of the transistors 455, 454 are coupled to the respective outputs (B[n](+/−)) of the 4:1 multiplexer 469.

The collector terminal of the transistor 461 is coupled to the common emitter terminals of the seventh differential pair transistors 456, 457. A pair of differential data signals (data3[n](+/−)) is provided to the base terminals of the respective transistors 457, 456. The collector terminals of the transistors 456, 457 are coupled to the respective outputs (B[n](+/−)) of the 4:1 multiplexer 469.

The differential select signals (se10, se11) control the conduction of transistors in the first three differential pair transistors. For example, when a select signal is active (i.e., logic high), the corresponding transistor is able to conduct current or on. Alternately, when the select signal is inactive (i.e., logic low), the corresponding transistor is off or unable to conduct current. Since each of the differential pair transistors is driven by differential signals, one of the transistors in each of the differential pair transistors is on at any given time while the other transistor in the pair is off.

Base on the differential select signals (se10, se11) from the multiplexer select circuit 408, the 4:1 multiplexer 469 selectively outputs the differential data signals in accordance with the Table I below.

TABLE I

| Sel1 | Sel0 | B[n] |
|---|---|---|
| 0 | 0 | Data1[n] |
| 0 | 1 | Data4[n] |
| 1 | 0 | Data2[n] |
| 1 | 1 | Data3[n] |

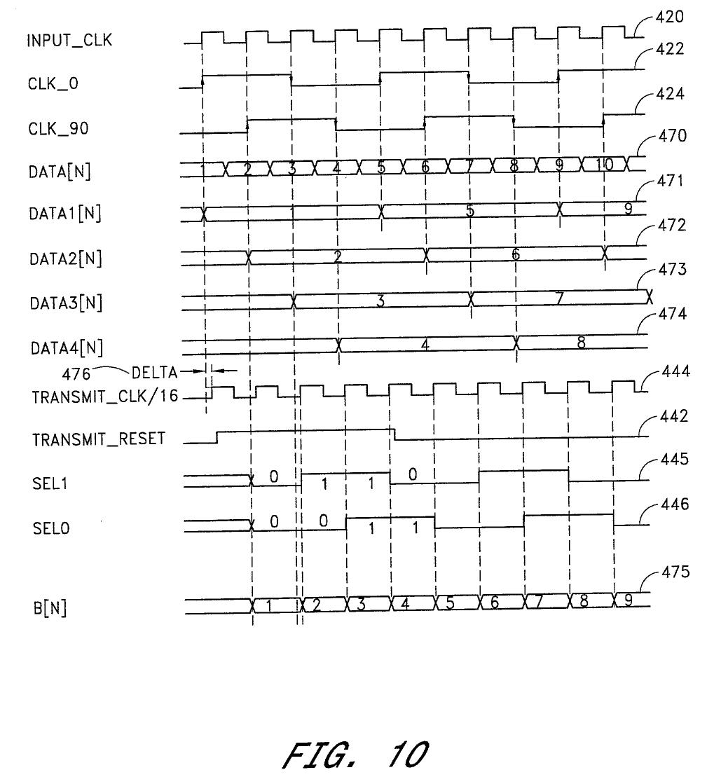

FIG. 10 is a timing diagram illustrating phase alignment of input data to a transmitter clock in accordance with the embodiment shown in FIG. 4. A graph 420 represents an input clock (input_clk). Graphs 422, 424 represent quarter-speed clocks (clk_0, clk_90) which are phase locked to the input clock, run at a quarter of the speed of the input clock, and are 90 degrees offset from each other. A graph 470 represents one bit (data[n]) of parallel input data (data[15:0]) which is substantially phase locked to the input clock.

Graphs 471, 472, 473, 474 represent demultiplexed versions of the input data. Data transitions of the first set of demultiplexed input data (data1 [n]) follow the rising edges of the zero degree quarter-speed clock (clk_0). Data transitions of the second set of demultiplexed input data (data2[n]) follow the rising edges of the 90 degrees quarter-speed clock (clk_90). Data transitions of the third set of demultiplexed input data (data3[n]) follow the falling edges of the zero degree quarter-speed clock (clk_0). Data transitions of the fourth set of demultiplexed input data {data4[n]) follow the falling edges of the 90 degrees quarter-speed clock (clk_90).

Graphs 444, 442, 445, 446 represent signals which were first introduced and discussed with respect to the timing diagrams of FIG. 8. As discussed above, the transmitter clock (transmit_clk/16) represented by the graph 444 in not necessarily phase locked with the input clock (input_clk ) represented by the graph 420. For example, an unknown difference (delta) 476 between the rising edges of the transmitter clock and the input clock can exist.

A graph 475 represents one of the output bits (B[n]) at the output of the phase alignment circuit 380. The output bit (B[n]) is a duplicate of the input data (data[n]). However, data transitions of the output bit (B[n]) are controlled by the select signals (se11, se10) which are phase locked to the transmitter clock. Therefore, the phase alignment circuit 380 accepts input data (data[15:0]) phase locked to an input clock (input_clk) and outputs data (B[15:0]) phase locked to a transmitter clock (transmit_clk/16).

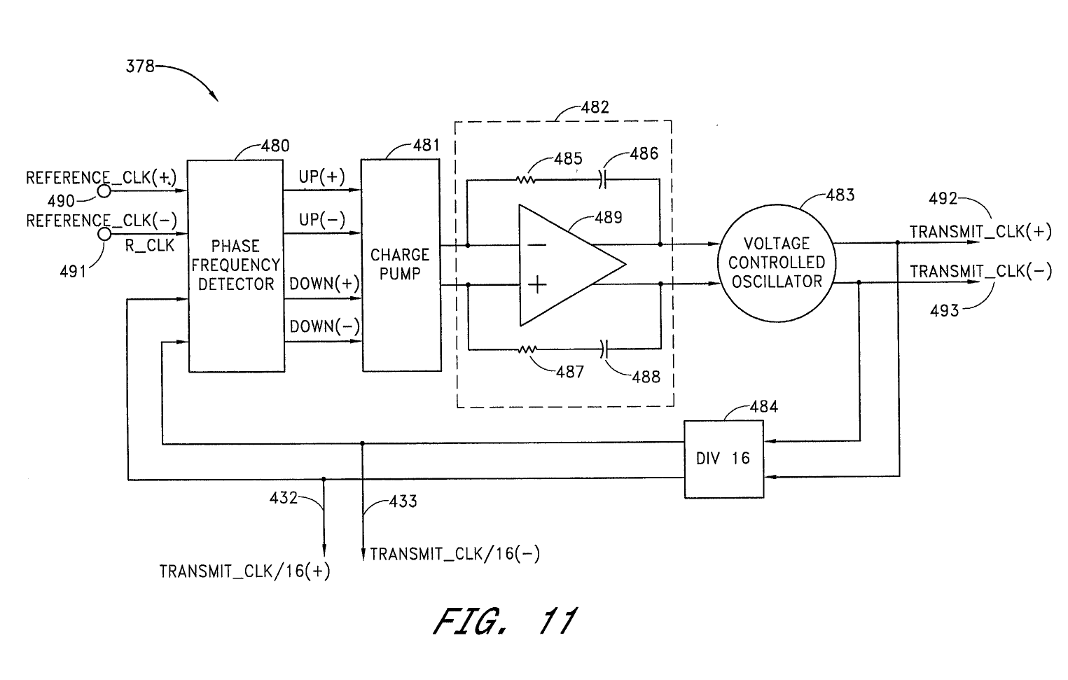

FIG. 11 illustrates one embodiment of a clock multiply unit (CMU) 378. The clock multiply unit 378 (phase lock loop) includes a phase frequency detector (PFD) 480, a charge pump 481, a loop filter 482, a voltage controlled oscillator (VCO) 483, and a divider 484. In one embodiment, the loop filter 482 includes an amplifier 489, a first integrating capacitor 486, a second integrating capacitor 488, a first resistor 485, and a second resistor 487. The first resistor 485 and the first integrating capacitor 486 are coupled in series between negative input and output terminals of the amplifier 489. The second resistor 487 and the second integrating capacitor 488 are coupled in series between positive input and output terminals of the amplifier 489.

A differential reference clock (reference_clk(+/−)) on clock lines 490, 491 is provided to inputs of the PFD 480. Differential outputs (transmit_clk/16(+/−)) of the divider 484 are also provided to inputs of the PFD 480. The PFD generates two pairs of differential signals (up(+/−), down(+/−)) which are provided to inputs of the charge pump 481. The charge pump 481 generates differential outputs which are coupled to inputs of the amplifier 489. Differential outputs of the amplifier 489 are coupled to inputs of the VCO 483. Differential outputs (transmit_clk(+/−)) of the VCO 483 are coupled to inputs of the divider 484. In one embodiment, the divider 484 divides the frequency of the VCO output by 16.

The CMU 378 outputs transmitter clocks (transmit_clk, transmit_clk/16) which are phase locked to the input reference clock (reference_clk) with frequencies that are multiples or sub-multiples of the input reference clock (reference_clk). For example, a first transmitter clock (transmit_clk/16) on clock lines 432, 433 at the output of the divider 484 has a frequency that is approximately the same frequency as the input reference clock, and a second transmitter clock (transmit_clk) on clock lines 492, 493 at the outputs of the VCO 483 has a frequency that is approximately 16 times the frequency as the input reference clock. The clock lines 432, 433 are differential versions of the clock line 368, and the clock lines 492, 493 are differential versions of the clock line 362 in FIG. 3A.

To generate the outputs of the CMU 378 described above, the PFD 480 compares the input reference clock (reference_clk) with the first transmitter clock (transmit_clk/16). When the frequency of the input reference clock is higher than the frequency of the first transmitter clock, the PFD 480 indicates that the input reference clock is faster than the first transmitter clock by activating an UP signal at the PFD output (i.e., up(+) pulses logic high for a duration corresponding a difference in frequency between the input reference clock and the first transmitter clock). Alternately, when the frequency of the input reference clock is lower than the frequency of the first transmitter clock, the PFD 480 indicates that the input reference clock is slower than the first transmitter clock by activating a DOWN signal at the PFD output (i.e., down(+) pulses logic high for a duration corresponding to a difference in frequency between the input reference clock and the first transmitter clock. The PFD 480 is explained in further detail below.

The outputs of the PFD 480 are provided to the charge pump 481 for conversion to current signals corresponding to pulse widths of the UP and DOWN signals. The current signals are converted to voltage signals by the loop filter 482. The voltage signals control the frequency of oscillation by the VCO 483. For example, an UP pulse increases the frequency of oscillation by the VCO 483, and a DOWN pulse decreases the frequency of oscillation by the VCO 483. In one embodiment, the VCO 483 is configured to oscillate at 16 times the frequency of the input reference signal.

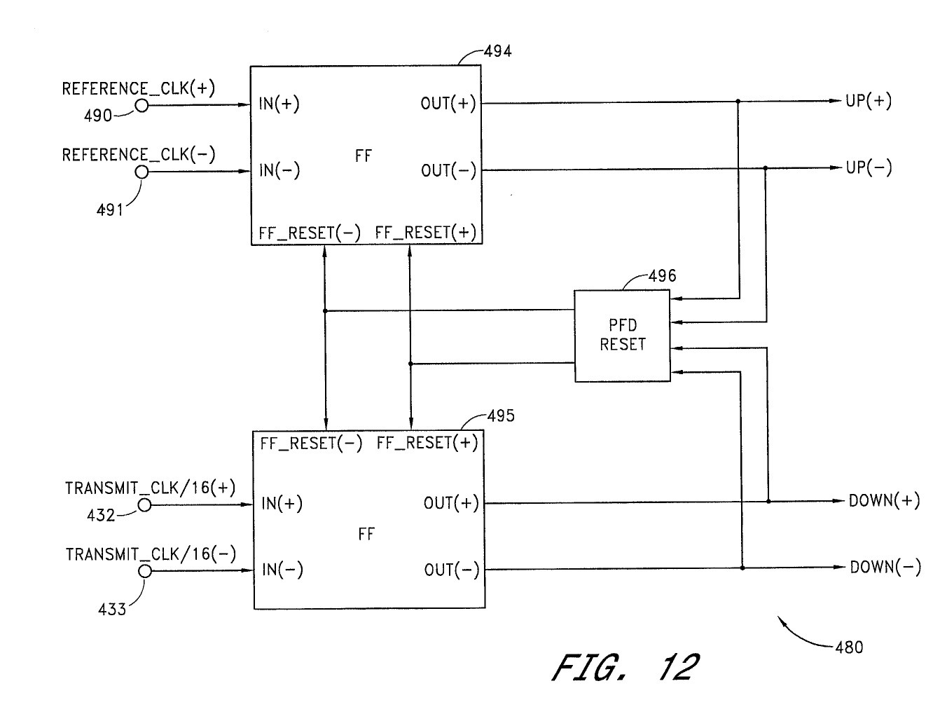

FIG. 12 illustrates one embodiment of a phase frequency detector (PFD) 480 in the clock multiply unit (CMU) 378. The PFD 480 includes two flip-flops (FFs) 494, 495 and a PFD reset circuit 496.

Differential input reference clocks (reference_clk(+/−)) on clock lines 490, 491 are provided to differential inputs (in(+/−)) of the first FF 494. The differential outputs of the first FF 494 (out(+/−)) are differential UP signals (up(+/−)) outputted by the PFD 480. The UP signal transitions to logic high on each rising edge of the input reference clock.

Differential first transmitter clocks (transmit_clk/16(+/−)) on clock lines 432, 433 are provided to differential inputs (in(+/−)) of the second FF 495. The differential outputs of the second FF 495 (out(+/−)) are differential DOWN signals (down(+/−)) outputted by the PFD 480. The DOWN signal transitions to logic high on each rising edge of the first transmitter clock.

The UP and DOWN signals are coupled to inputs of the PFD reset circuit 496. Differential reset outputs of the PFD reset circuit 496 are coupled to differential reset inputs (FF_reset(+/−)) of the FFs 494, 495. The PFD reset circuit 496 detects the condition when both the UP and DOWN signals are logic high and outputs a reset signal to reset both of the FFs 494, 495 (i.e., reset the UP and DOWN signals to logic low). Advantageously, the reset signal has a minimum pulse width and is active until both the UP and DOWN signals are logic low. The PFD reset circuit 496 is discussed in further detail below.

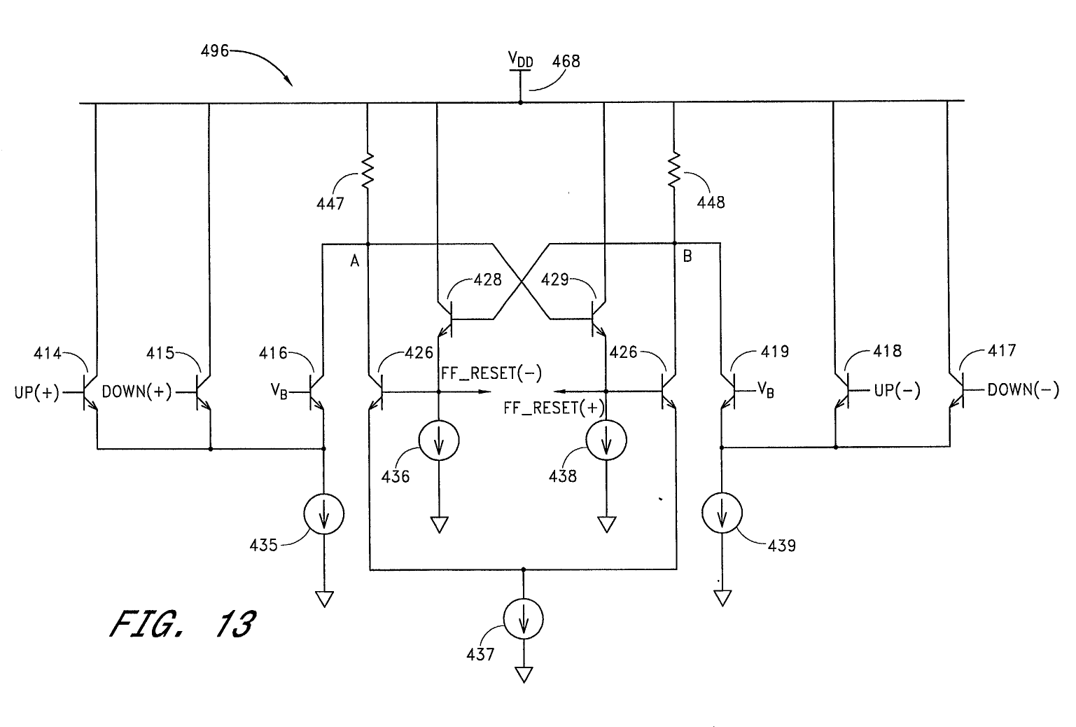

FIG. 13 illustrates one embodiment of a phase frequency detector (PFD) reset circuit 496 shown in FIG. 12. The PFD reset circuit 496 includes a first set of transistors 414, 415, 416 whose emitter terminals are commonly connected and coupled to a first current source 435, a second set of transistors 417, 418, 419 whose emitter terminals are commonly connected and coupled to a second current source 439, differential pair transistors 426, 427 whose emitter terminals are commonly connected and coupled to a third current source 437, a transistor 428 whose emitter terminal is coupled to a fourth current source 436, a transistor 429 whose emitter terminal is coupled to a fifth current source 438, a first resistor 447, and a second resistor 448. In one embodiment, the floating terminals of the current sources 435, 436, 437, 438, 439 are coupled to ground.

In one embodiment, collector terminals of the transistors 414, 415, 417, 418 couple to a voltage source (VDD) 468. Base terminals of the transistors 414, 418 couple to a differential UP signal (i.e., the base terminal of the transistor 414 couples to the positive UP signal (up(+)), and the base terminal of the transistor 418 couples to the negative UP signal (up(−))). Base terminals of the transistors 415, 417 couple to a differential DOWN signal (i.e., the base terminal of the transistor 415 couples to the positive DOWN signal (down(+)), and the base terminal of the transistor 417 the negative DOWN signal (down(−))).

Collector terminals of the transistors 416, 426 are commonly connected at node A. The first resistor 447 is connected between node A and VDD 468. Collector terminals of the transistors 419, 427 are commonly connected at node B. The second resistor 448 is connected between node B and VDD 468. A bias voltage (Vb) is provided to base terminals of the transistors 416, 419. In one embodiment, the bias voltage (Vb) is the average voltage of the UP and DOWN signals. Base terminals of the transistors 427, 426 are coupled to the emitter terminals of the transistors 429, 428 which are differential reset outputs (FF_reset(+/−)) of the PFD reset circuit 496.

Collector terminals of the transistors 428, 429 connect to VDD 468. Base terminal of the transistor 429 couples to node A. Base terminal of the transistor 428 couples to node B. The transistors 428, 429 are a pair of emitter followers (i.e., the logic of the transistor 428 output (FF_reset(−)) at its emitter terminal follows the logic of the transistor 428 input at node B, and the logic of the transistor 429 output (FF_reset(+)) at its emitter terminal follows the logic of the transistor 429 input at node A). The logic levels at nodes A and B are determined by the differential UP and DOWN signal inputs to the PFD reset circuit 496 and the logic levels of the PFD reset circuit outputs (FF_reset).

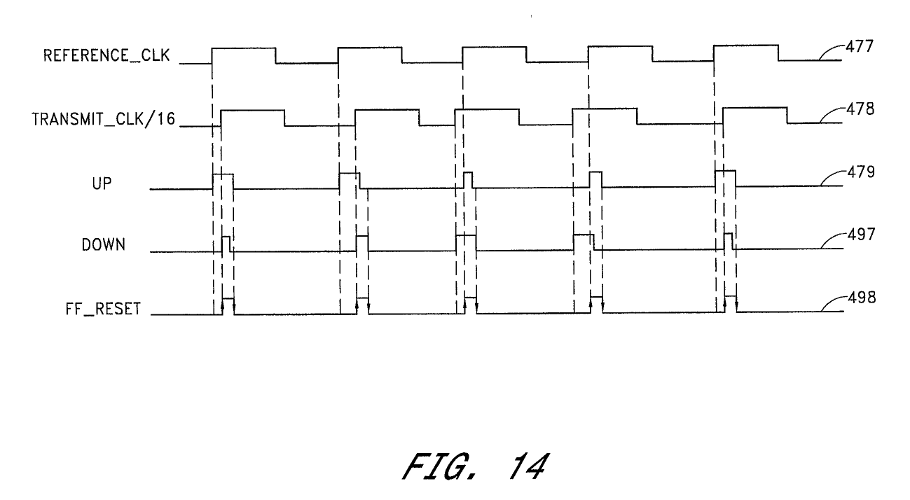

FIG. 14 is a timing diagram of the phase frequency detector (PFD) 480 of FIG. 12. A graph 477 represents a reference clock (reference_clk). A graph 478 represents a first transmitter clock (transmit_clk/16). A graph 479 represents an UP signal. A graph 497 represents a DOWN signal. A graph 498 represents a FF reset signal (FF_reset).

In one embodiment, the reference clock is approximately 622 MHz. The CMU 378 functions to phase and frequency lock the first transmitter clock to the reference clock. The PFD 480 generates the UP and DOWN signals which has rising edges following the rising edges of the respective reference clock and the first transmitter clock. When both the UP and DOWN signals are logic high, the PFD 480 generates the reset signal (FF₁₃ reset) to reset itself (i.e., bring both the UP and DOWN signals to logic low). The relative width of the UP and DOWN signals indicates a speed difference between the reference clock and the first transmitter clock.

Advantageously, the reset signal (FF_reset) is active until both the UP and DOWN signals have transitioned to logic low. The PFD 480 resets properly (i.e., both UP and DOWN signals transition to logic low) each time and is not hindered by delay differences between the FFs 494, 495 in the PFD 480. The PFD 480 is capable of detecting relatively small differences between the reference clock frequency and the first transmitter clock frequency. Thus, the PFD is capable of operating at relatively high-speeds.

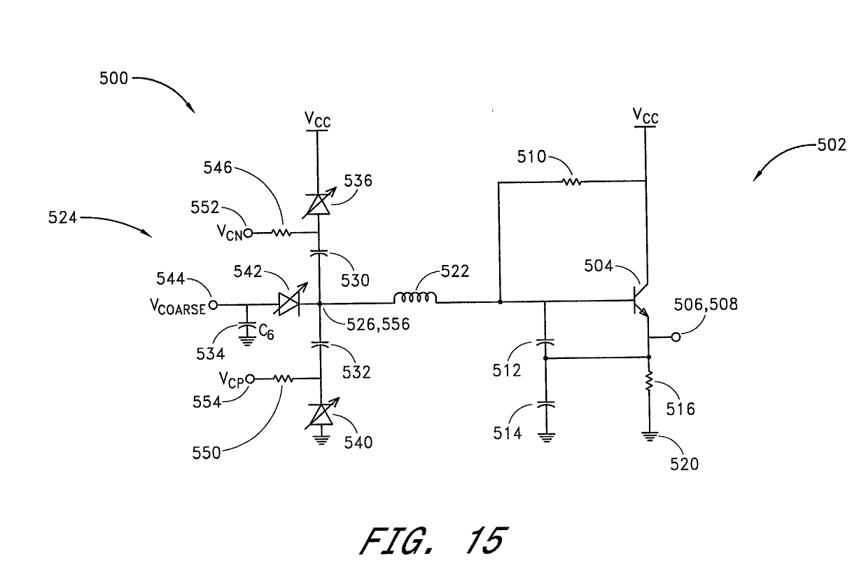

FIG. 15 illustrates one embodiment of an enhanced Colpitts voltage controlled oscillator (VCO) 500 of the present invention. The enhanced VCO 500 automatically acquires and maintains an oscillating output at a regulated frequency. The periodic output is maintained in synch with other system clocks to facilitate generating a high frequency, serial output in a manner that will be described in greater detail below. The enhancement of the present invention partially comprises improved tuning of the VCO 500 including separate coarse tuning to increase the speed of acquisition of a desired frequency range and fine tuning that employs a differential signal to offer improved common mode rejection and noise immunity as well as better resolution of the oscillating frequency. In certain embodiments, the VCO 500 is particularly well adapted for use in a clock multiply unit 378, however, can also be adapted for use in a variety of circuit applications as will become apparent to one of skill in the art after considering the more detailed description of this aspect of the invention as follows.

The enhanced Colpitts VCO 500 of this embodiment, comprises a negative resistance element 502. The negative resistance element 502 facilitates the establishment of a self-initiating and sustaining electrical oscillation from the enhanced VCO 500 in a manner well understood in the art. The negative resistance element 502 in this embodiment, is an active circuit element and comprises an n-type transistor 504. The collector of the transistor 504 is connected directly to a supply voltage which, in this embodiment, is approximately 3.3V. The emitter of the transistor 504 defines an output 506 of the enhanced VCO 500. It will be appreciated that in certain embodiments, an additional output circuit element, such as a transistor can be interposed between the output 506 and downstream circuits. It will also be appreciated that in certain embodiments, the transistor 504 can include multiple transistors 504 connected in parallel to provide increased drive capacity.

The negative resistance element 502 also comprises a resistor 510 connected between the collector and the base of the transistor 504. In this embodiment, the resistor 510 is a 5 kΩ resistor. The negative resistance element 502 also comprises two capacitors 512, 514 connected in series between the base of the transistor 504 and circuit ground 520. One leg of the capacitor 512 is connected to the base of the transistor 504 and the other leg of the capacitor 512 is connected to a first leg of the capacitor 514. The second leg of the capacitor 514 is connected to circuit ground 520. The negative resistance element 502 also comprises a resistor 516 connected between the first leg of the capacitor 514 and circuit ground 520. The resistor 516 is also connected between the emitter of the transistor 504 and circuit ground 520.

The enhanced VCO 500 also comprises an inductor 522. A first leg of the inductor 522 is connected to the base of the transistor 504. The second leg of the inductor 522 is connected to a node 526 of a variable capacitance and voltage network 524. The variable capacitance and voltage network 524 provides a variable, regulated capacitance C_{Eff} 556 at the node 526 to facilitate regulating the frequency of oscillation of the enhanced VCO 500 in a manner that will be described in greater detail below. It will be appreciated to one of skill in the art that varying the effective capacitance C_{Eff} 556 at node 526 will vary the oscillation frequency of the enhanced VCO 500 in a well-known manner.

The variable capacitance and voltage network 524 of this embodiment also comprises fixed capacitors 530, 532, and 534 and voltage controlled, variable capacitors (varactors) 536, 540, and 542. The capacitor 530 and the varactor 536 are connected together in series between the node 526 and the supply voltage. The capacitor 532 and the varactor 540 are connected together in series between the node 526 and circuit ground 520.

The capacitor 534 and the varactor 542 are connected together in series between the node 526 and circuit ground 520. The connection between the capacitor 534 and the varactor 542 define a coarse frequency adjustment node V_{Coarse} 544. A variable voltage is supplied to the coarse frequency adjustment node V_{Coarse} 544 to enable the enhanced VCO 500 to set a coarse range of frequencies of oscillation. The manner in which the variable voltage is provided to the coarse frequency adjustment node V_{Coarse} 544 will be described in greater detail below.

The variable capacitance and voltage network 524 of this embodiment also comprises resistors 546, 550. A first leg of the resistor 546 is connected to the connection between the capacitor 530 and the varactor 536. The second leg of the resistor 546 defines an input node V_{CN} 552. A first leg of the resistor 550 is connected to the connection between the capacitor 532 and the varactor 540. The second leg of the resistor 546 defines an input node V_{CP} 554. The input nodes V_{CN} 552 and V_{CP} 554 form a differential input to enable fine tuning of the oscillation frequency of the enhanced VCO 500 in a manner that will be described in greater detail below. The resistors 546, 550 in this embodiment are each 10 kΩ.

It will be appreciated by one of skill in the art that the capacitors 530, 532, and 534 and the varactors 536, 540, and 542 connected as previously described together define an effective capacitance C_{Eff} 556 looking into node 526. This C_{Eff} 556 in series with the inductor 522 form an oscillating circuit with the negative resistance element 502. The active transistor 504 will return lost resistive energy in the enhanced VCO 500 thereby enabling a sustained oscillation at the output 506. The control signals V_{Coarse} 544, V_{CN} 552, and V_{CP} 554 are employed to vary C_{Eff} 556 thereby varying and regulating the frequency of oscillation of the enhanced VCO 500.

In one embodiment, the enhanced Colpitts VCO 500 is part of the VCO 483 shown in FIG. 11. The loop filter 482 preceding the VCO 483 provides the differential control voltage signals (i.e., V_{CN} 552 and V_{CP} 554). A single-to-differential circuit (not shown) coupled to the enhanced VCO output 506 produces the differential transmitter clock (transmit_clk) on the clock lines 492, 493.

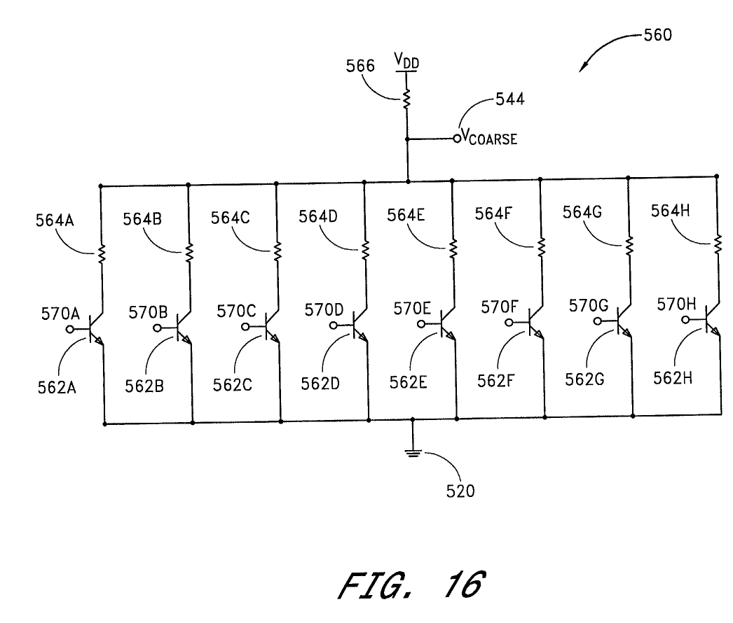

The enhanced VCO 500 also comprises a selectable voltage source 560 as illustrated in one embodiment in FIG. 16. The selectable voltage source 560 provides the coarse frequency adjustment node V_{Coarse} 544. In this embodiment, V_{Coarse} 544 is selectable between 8 different voltage values. Providing different values of V_{Coarse} 544 will change the value of the varactor 542 and thus provide different frequencies of oscillation for the enhanced VCO 500. The selectable voltage source 560 of this embodiment comprises transistors 562a-h, resistors 564a-h, and a resistor 566. The transistors 562a-h in this embodiment are n-type formed in a well known manner.

The emitters of the transistors 562a-h are connected to circuit ground 520. The collectors of the transistors 562a-h are connected to a first leg of one of the resistors 564a-h respectively. The second leg of each of the resistors 564a-h is connected to a first leg of the resistor 566 and the connection thereof defines V_{Coarse} 544. The second leg of the resistor 566 is connected to the supply voltage. The base of each of the transistors 562a-h each receives a control signal V_{C0}−V_{C7} 570a-h respectively. The control signals V_{C0}−V_{C7} 570a-h selectively enable one of the transistors 562a-h at a time and the control signals V_{C0}−V_{C7}, 570a-h are generated in a manner that will be described in greater detail below. In this embodiment, control signal V_{C0} 570a active gives the minimum frequency of oscillation range from the enhanced VCO 500 and control signal V_{C7} 570 h active gives the maximum frequency range.

In this embodiment, the resistors 564a-h have the following approximate values in ohms: 564a=55 k, 564b=24 k, 564c=14 k, 564d=8 k, 564e=4.8 k, 564f=2.8 k, 564g=1.3 k, 564h=0. The resistor 566 has the value of approximately 5 kΩ in this embodiment.

It should appreciated that in alternative embodiments, the selectable voltage source 560 provides fewer or more than 8 different voltage values and the control signals V_{C0}−V_{C7} 570a-h can activate a plurality of the transistors 562a-h in combination.

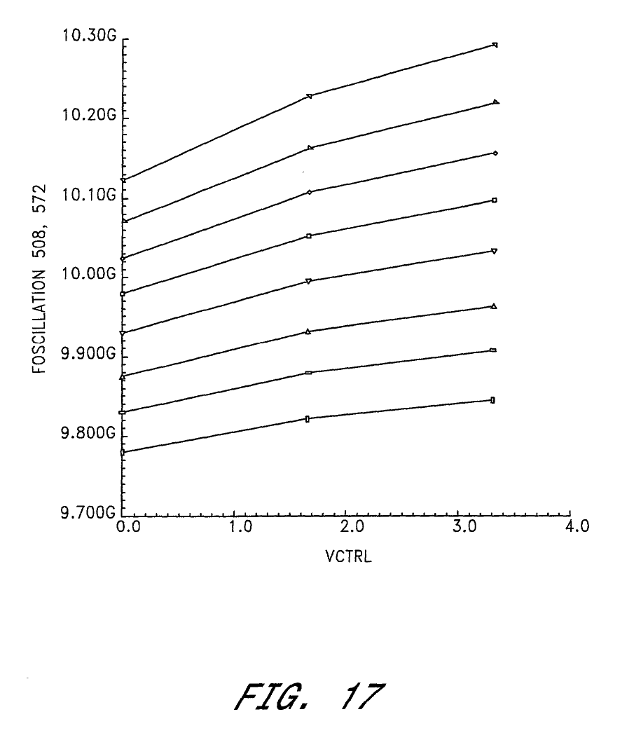

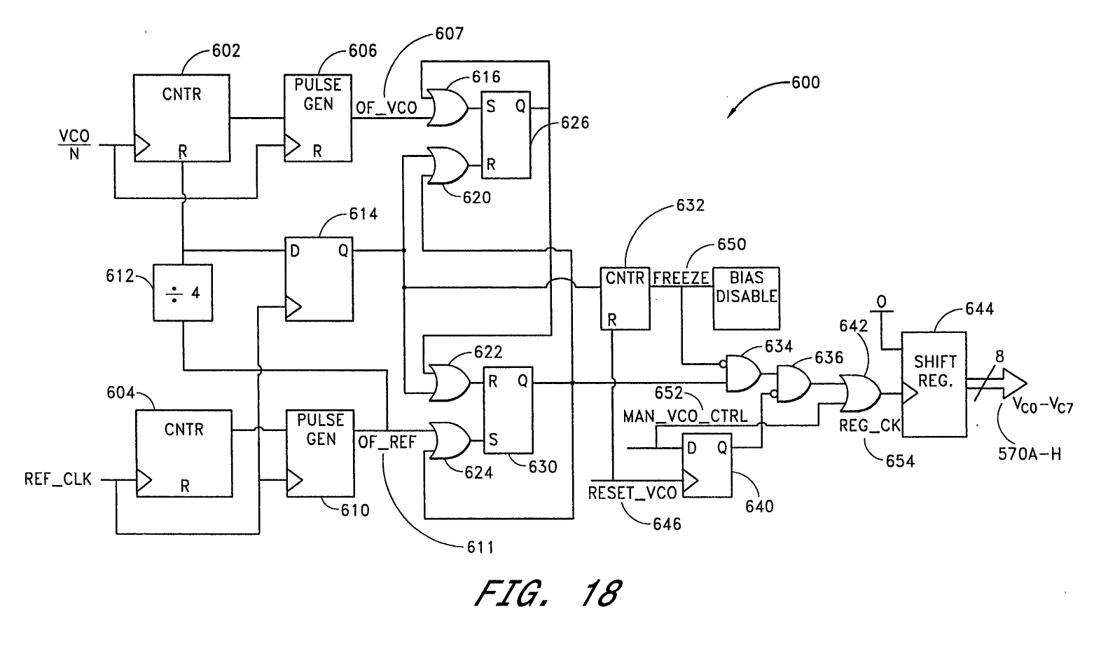

FIG. 17 is a graph of one embodiment of oscillation frequency 508 of the enhanced VCO 500 vs. voltage. The voltage illustrated in FIG. 17 comprises both the selected V_{Coarse} 544 and V_{CN} 552 and V_{CP} 554. Each curve in FIG. 17 defines a frequency range 572a-h for a given V_{Coarse} 544 corresponding to a different control signal V_{C0}−V_{C7} 570a-h active. The extent of each frequency range 572a-h corresponds to the adjustability provided by the control signals V_{CN} 552 and V_{CP} 554. It should be noted that each curve of the frequency ranges 572a-h partially overlaps adjacent curves. This aspect of the enhanced VCO 500 helps ensure that acquisition of a particular frequency 508 is achievable from a plurality of V_{Coarse} 544 selections.

As previously described, the enhanced VCO 500 defines a C_{Eff} 556 looking into node 526. In this embodiment, C_{Eff} 556 is defined by the parallel connection of the varactor 546 in series with the capacitor 530, the varactor 540 in series with the capacitor 532, and the varactor 542 in series with the capacitor 534. For purposes of explanation, capacitors 530 and 532 are assumed to be equal and are given the value C. The varactors 540 and 546 are likewise assumed to have the same initial value, Cᵥ. The change in Cᵥ due to the applied voltages V_{CN} 552 and V_{CP} 554 will be assigned the value ΔC. It should be appreciated that in alternative embodiments, the values of capacitors 530 and 532 and varactors 540 and 546 can be unequal. The values of the capacitor 534 and varactor 542 are given as C_{Coarse} and C_{VCoarse} respectively.

Thus, in this embodiment,

$${C}_{Eff} 556 = 2 \frac{( C \cdot CV )}{( C + CV )} + \frac{( CCoarse \cdot CVCoarse )}{( CCoarse + CVCoarse )} .$$

The value of ΔC can be either positive or negative depending on the sign of V_{CN} 552 and V_{CP} 554. Again, for illustration purposes, V_{CN} 552 and V_{CP} 554 will be assumed to be equal in magnitude and of opposite sign, however it should be appreciated that in alternative embodiments, V_{CN} 552 and V_{CP} 554 can vary both in magnitude and sign from each other. For V_{CN} 552 and V_{CP} 554 both increasing in value, the new C_{Eff} 556 will be given by

$${C}_{Eff} 556 = \frac{C ( CV + Δ C )}{C + ( CV + Δ C )} + \frac{C ( CV - Δ C )}{C + ( CV - Δ C )} + \frac{( CCoarse \cdot CVCoarse )}{( CCoarse + CVCoarse )} .$$

It will be appreciated by one of skill in the art that, in this circumstance, for both V_{CN} 552 and V_{CP} 554 increasing the first term of C_{Eff} 556 increases while the second term decreases and the third term remains the same. Thus, for V_{CN} 552 and V_{CP} 554 both increasing, i.e. exhibiting a common mode effect or a characteristic of noise, the changes in the varactors 546 and 540 tend to offset and minimize the overall change to C_{Eff} 556. In a complementary fashion, for V_{CN} 552 and V_{CP} 554 both decreasing, C_{Eff} 556 will be given by

$${C}_{Eff} 556 = \frac{C ( CV - Δ C )}{C + ( CV - Δ C )} + \frac{C ( CV + Δ C )}{C + ( CV + Δ C )} + \frac{( CCoarse \cdot CVCoarse )}{( CCoarse + CVCoarse )} .$$

In this circumstance the first term of C_{Eff} 556 tends to decrease while the second term increases and the third term again remains unchanged. Again, for a DC change in V_{CN} 552 and V_{CP} 554, the changes in varactors 546 and 540 tend to offset and minimize the overall change to C_{Eff} 556. For the desirable circumstance, where V_{CN} 552 and V_{CP} 554 operate in a differential manner, C_{Eff} 556 will be given by

$${C}_{Eff} 556 = \frac{2 C ( CV - Δ C )}{C + ( CV - Δ C )} + \frac{( CCoarse \cdot CVCoarse )}{( CCoarse + CVCoarse )} or$$

$${C}_{Eff} 556 = \frac{2 C ( CV + Δ C )}{C + ( CV + Δ C )} + \frac{( CCoarse \cdot CVCoarse )}{( CCoarse + CVCoarse )} .$$

Thus, the differential fine tuning of the enhanced VCO 500 of this embodiment inhibits variation in the frequency of oscillation 508 when the control signals V_{CN} 552 and V_{CP} 554 change together thereby offering improved noise immunity yet facilitate adjustment to the frequency of oscillation 508 when the control signals V_{CN} 552 and V_{CP} 554 operate in a differential fashion.

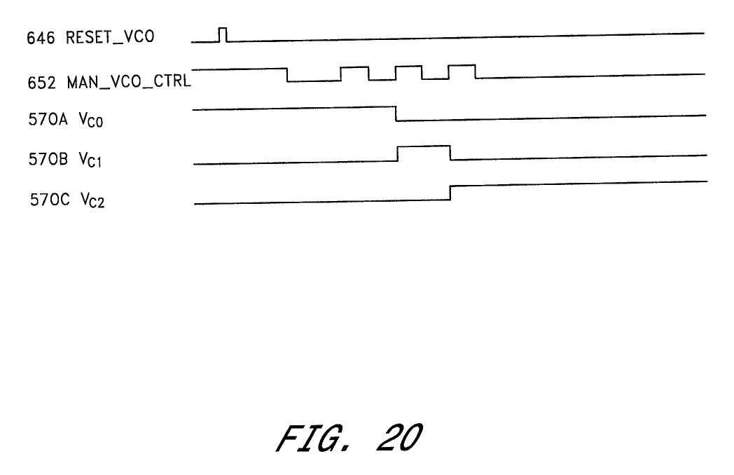

The enhanced VCO 500 also comprises a digital search circuit 600. The digital search circuit 600 automatically determines and provides the control signals V_{C0}−V_{C7} 570a-h to enable the selectable voltage source 560 to provide the appropriate coarse tuning voltage V_{Coarse} 544. In one embodiment, the digital search circuit 600 compares a sub-multiple frequency of oscillation of the enhanced VCO 500 to a frequency of a reference clock (REF_CLK). For example, the VCO 500 output frequency 508 is divided by 16. In one embodiment, the reference clock (REF_CLK) is the differential reference clock (reference_clk(+/−)) on the clock lines 490, 491. The digital search circuit 600 essentially establishes and monitors a plurality of races between a clock referenced to the enhanced VCO output 506 and the REF_CLK 332 and increases V_{Coarse} 544 until the frequency 508 of the VCO 500 is at least as great as REF_CLK 332. In this embodiment, the digital search circuit 600 begins with the lowest V_{Coarse} 544 which corresponds to control signal 570a active and correspondingly transistor 562a. The digital search circuit 600 then increments the active transistor 562a-h one at a time, as needed, to achieve the desired VCO frequency 508. FIG. 20 is a flow chart illustrating one embodiment of this decision process.

In this embodiment, the digital search circuit 600 comprises counters 602, 604. In this embodiment, the counters 602, 604 are each 10 bit counters of a type well known in the art. The counter 602 receives, as input, the enhanced VCO output 506, divided by 16. The counter 604 receives as input the REF_CLK 332 signal. The digital search circuit 600 also comprises pulse generators 606, 610 each receiving as input the output of the counters 602, 604 respectively. The pulse generators 606, 610 generate output signals OF_VCO 607 and OF_REF 611 respectively wherein the output signals OF_VCO 607 and OF_REF 611 each indicate an overflow condition from the respective counters 602, 604. The digital search circuit 600 monitors which of the output signals OF_VCO 607 and OF_REF 611 occurs first in order to determine whether V_{Coarse} 544 needs to be increased, i.e. whether the output frequency 508 of the enhanced VCO 500 needs to be increased.

The digital search circuit 600 also comprises a divider 612. The divider 612 of this embodiment receives the output signal OF_REF 611 and divides that signal by 4. The output of the divider 612 goes to a reset input of the counter 602 to reset the count thereof back to zero. The output of the divider 612 also goes to the “D” input of a D flip-flop 614. The enhanced VCO output 506, divided by 16 signal also clocks the pulse generator 606 and the REF_CLK 332 signal clocks the pulse generator 610 and the D flip-flop 614.

The digital search circuit 600 also comprises OR gates 616, 620, 622, 624 and S-R flip-flops 626, 630. The outputs of the OR gates 616, 620 are connected to the S and R inputs respectively of the S-R flip-flop 626. The outputs of the OR gates 622, 624 are connected to the R and S inputs respectively of the S-R flip-flop 630. The Q output of the S-R flip-flop 626 is one input of the OR gates 616 and 622. The other input of the OR gate 616 is the OF_VCO 607 signal. The Q output of the D flip-flop 614 is one input of each of the OR gates 620 and 622. The Q output of the S-R flip-flop 630 is one input of the OR gates 620 and 624. The other input of the OR gate 624 is the OF_REF 611 signal.

The digital search circuit 600 of this embodiment also comprises a counter 632, two modified AND gates 634, 636, a D flip-flop 640, an OR gate 642, and a shift register 644. The modified AND gates 634, 636 of this embodiment are two input devices and perform the standard AND function except that one of the inputs is inverting. The counter 632 of this embodiment is a 4 bit counter of a type well known in the art and receives as input the output of the D flip-flop 614. A RESET_VCO 646 signal goes to the counter 632 as a reset input and also clocks the D flip-flop 640. A MAN_VCO_CTRL 652 signal is the input to the D flip-flop 640 and also is an input of the OR gate 642. The output of the counter 632 comprises a FREEZE 650 signal that goes to the inverting input of the modified AND gate 634. The non-inverting input of the modified AND gate receives as input the Q output of the S-R flip-flop 630.

The output of the modified AND gate 634 goes to the standard input of the modified AND gate 636. The inverting input of the modified AND gate 636 receives as input the Q output of the D flip-flop 640. The output of the modified AND gate 642 forms the other input of the OR gate 642. The output of the OR gate 642 clocks the shift register 644. The input of the shift register 644 is tied to logic low. The shift register 644 of this embodiment is an 8 bit register of a type well known in the art and is initially loaded with a count of “1”. Thus, each active output of the OR gate 642 clocks in a “0” count and shifts the “1” one position to the right. The outputs of the shift register 644 are the eight V_{C0}−V_{C7} control signals 570a-h. The initial active output of the shift register 644, corresponding to the initial “1” count, corresponds to control signal V_{C0} 570a active and thus to the lowest coarse frequency setting. Each increment of the shift register 644 will enable the next V_{C0}−V_{C7} control signal 570a-h and thus the next greater V_{Coarse} 544 setting.

As previously described, the VCO output 506 divided by 16 signal enters the counter 602 and the REF_CLK 332 signal enters the counter 604. Each of the counters 602, 604 in this embodiment counts 2¹⁰−1 or 1023 clock events before overflowing and resetting to zero count. Filling the counters 602, 604 generates an overflow signal to the pulse generators 606, 610 respectively which generate the OF_VCO 607 and OF_REF 611 signals respectively. The OF_REF 611 signal also goes to the divider 612 and, after four events, resets the counter 602. Thus, the counter 602 is reset every four overflows of the counter 604. In this embodiment, the initial V_{Coarse} 544 is selected such that VCO output 506 divided by 16 is less than REF_CLK 332. Thus, the counter 602 will be reset in a slave relationship by the counter 604 until VCO output 506 divided by 16 exceeds REF_CLK 332. The divider 612 is included to allow extra time between reset events of the counter 602. The REF_CLK 332 signal in this embodiment is at 622 MHz and thus an OF_REF 611 signal occurs approximately every 1.646 μs.

The MAN_VCO_CTRL 652 signal increments the shift register 644 by 1 and thus increases the V_{Coarse} 544 setting. This provision enables overriding the automatic operation of the digital search circuit 600 as previously described to set the enhanced VCO 500 output frequency 508 in an alternative manner.

The FREEZE 650 signal becomes active upon the counter 632 overflowing. In one embodiment, this condition corresponds to the counter 632 counting to ten races. The FREEZE 650 signal disables the digital search circuit 600 such that the presently selected V_{Coarse} 544 value is maintained. The FREEZE 650 acts as a failsafe to inhibit continuous operation of the digital search circuit 600 in case of circuit malfunction. As the shift register 644 and the selectable voltage source 560 of this embodiment have 8 different values, exceeding ten races would typically be abnormal operation for the enhanced VCO 500 of this embodiment and is thus inhibited. The RESET_VCO 646 signal performs a power on reset of the enhanced VCO 500 and clears the FREEZE 650 signal. During normal operation of the races between VCO output 506 divided by 16 and REF_CLK 332, the FREEZE 650 will normally be at logic low.

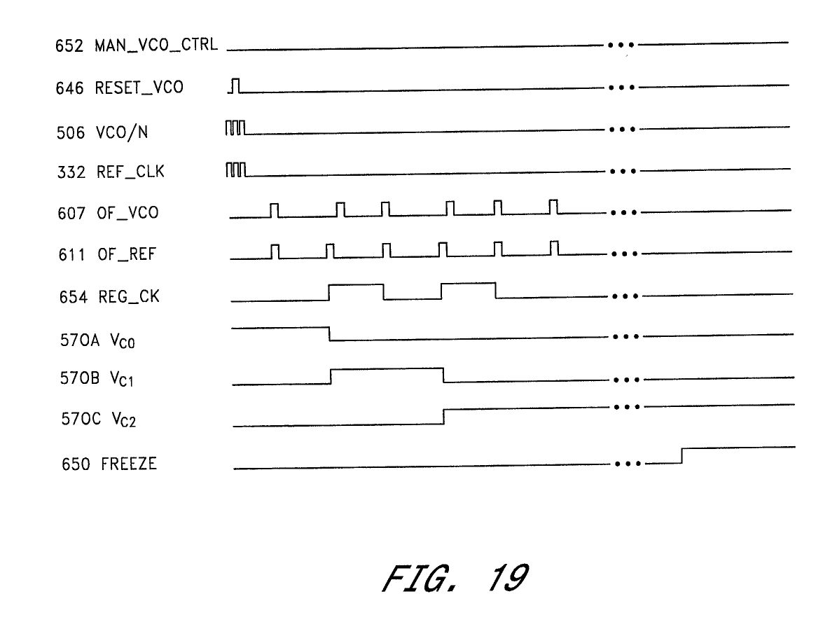

FIG. 19 is a timing diagram of one embodiment of an automatic search mode 700 of the digital search circuit 600. In this embodiment, the MAN_VCO_CTRL 652 signal is low throughout. The RESET_VCO 646 signal going high initiates VCO 500 operation resulting in the VCO output 506 signal. As previously described, filling the counters 602, 604 results in the generation of the OF_VCO 607 and OF_REF 611 signals respectively. In this embodiment, the VCO output frequency 508 divided by 16 is initially less than the REF_CLK 332 frequency. Because of the large number of cycles before OF_VCO 607 and OF_REF 611 occur (1024 in this embodiment), FIG. 19 does not illustrate the individual clock cycles of the VCO output 506 or REF_CLK 332 and in lieu thereof, the relative occurrence of the OF_VCO 607 and OF_REF 611 are used as indicia of the relative speed of the VCO output 506 and REF_CLK 322 frequencies. It should be understood therefor that the VCO output frequency 508 divided by 16 and the REF_CLK 332 signals illustrated in FIG. 19 are not to scale.

In this embodiment, V_{C0} 570a is initially active. Upon completion of the first race between the VCO output 506 divided by 16 and REF_CLK 332, REF_CLK 332 is faster resulting in a REG_CK 654 signal which disables V_{C0} 570a and enables V_{C1} 570b which increases the VCO output frequency 508. Upon completion of the second race, REG_CK 654 is again active resulting in V_{C1} 570b being disabled and V_{C2} 570c being enabled. In this embodiment, subsequent races result in the VCO frequency 508 being at least the frequency of REF_CLK 332 and thus no further adjustments to V_{Coarse} 544 are required. It should be appreciated that in alternative embodiments, fewer or more races would be required to acquire the needed V_{Coarse} 544. The automatic search mode 700 terminates upon the activation of the FREEZE signal 650 in the manner previously described.

FIG. 20 illustrates one embodiment of a manual mode 750 of the enhanced VCO 500. In this embodiment, the MAN_VCO_CTRL 652 signal is used to set V_{Coarse} 544. The RESET_VCO 646 signal activates operation of the enhanced VCO output 506. The MAN_VCO_CTRL 652 signal sequentially enables the control signals 570a-h one at time in the manner previously described. FIG. 20 illustrates the enablement of up through V_{C2} however it should be appreciated that the remaining values of V_{Coarse} 544 can be selected by additional occurrences of MAN_VCO_CTRL 652 active in other embodiments.

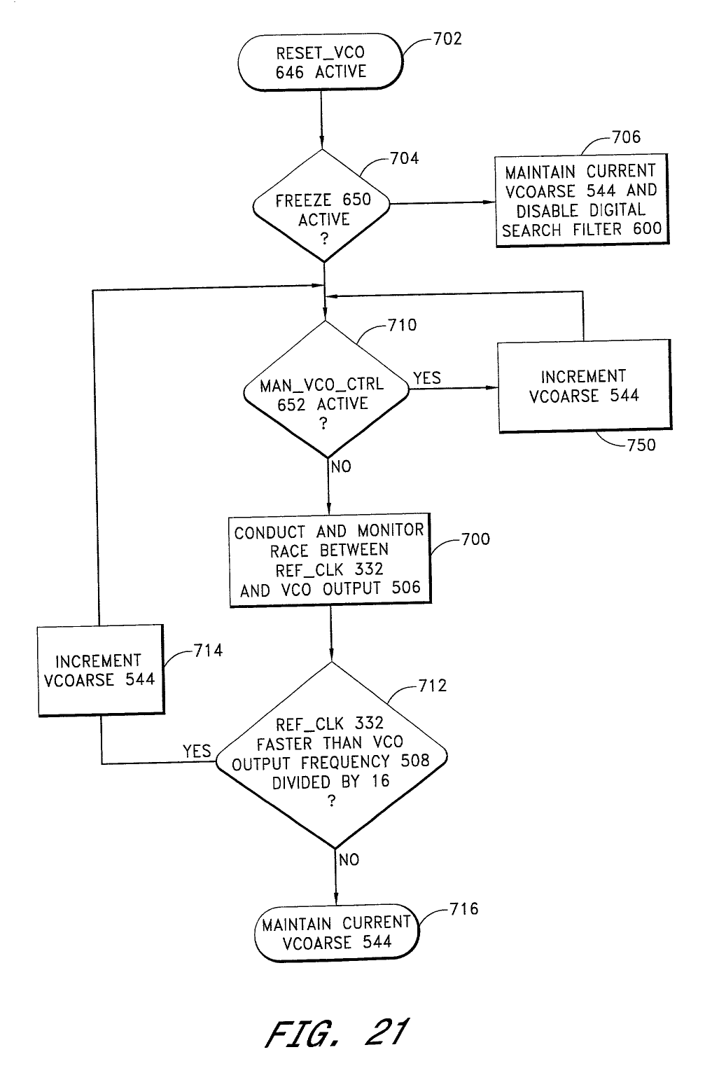

FIG. 21 is a flow chart illustrating the operation of both the automatic search mode 700 and the manual mode 750 of the enhanced VCO 500. Both the automatic search mode 700 and the manual mode 750 begin in state 702 with the activation of the RESET_VCO 646 signal. The enhanced VCO 500 then determines in state 704 whether the FREEZE 659 signal is active. If FREEZE 650 is active, the digital search circuit 600 is disabled and the currently selected V_{Coarse} 544 is maintained in state 706.

If FREEZE 650 is not active, the enhanced VCO 500 then determines in state 710 whether MAN_VCO_CTRL 652 is active. If MAN_VCO_CTRL 652 is active, the enhanced VCO 500 is in manual mode 750 and increments V_{Coarse} 544. If MAN_VCO_CTRL 652 is not active, then the enhanced VCO 500 is in automatic search mode 700 and conducts and monitors races between REF_CLK 332 and the VCO output 506 in the manner previously described.

The enhanced VCO 500 determines in state 712 whether REF_CLK 332 is faster than the VCO output frequency 508 divided by 16. If it is, the enhanced VCO 500 increments V_{Coarse} 544 in the manner previously described in state 714. If REF_CLK 332 is not faster, the enhanced VCO 500 maintains the current V_{Coarse} 544 in state 716.

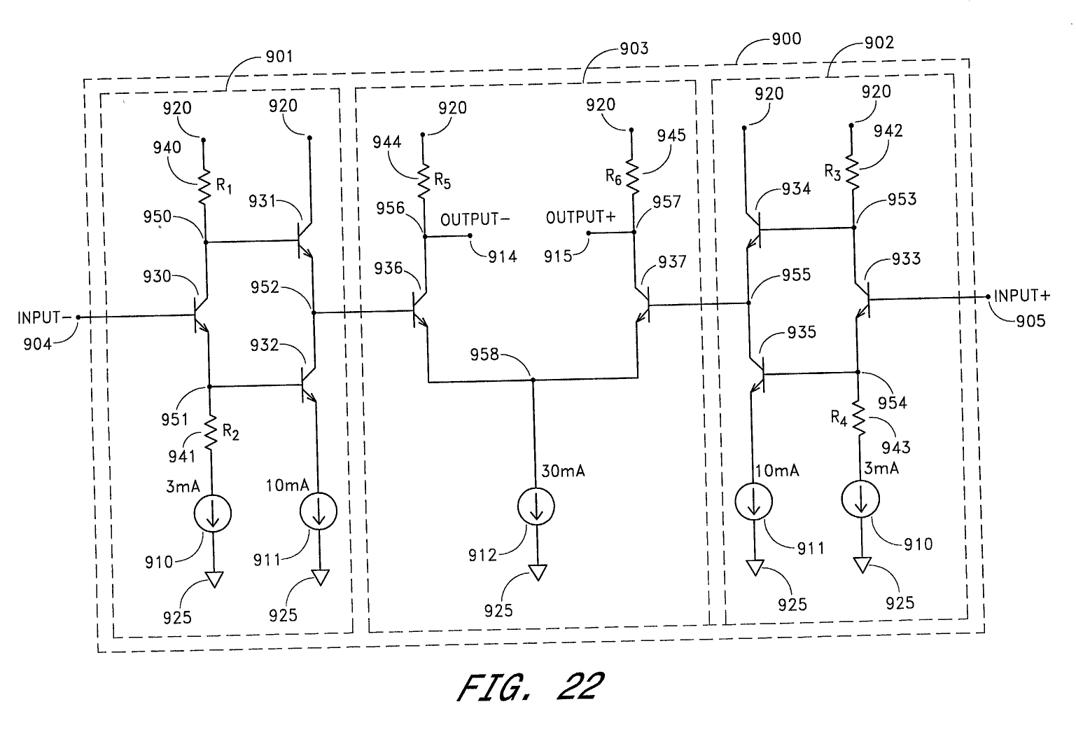

FIG. 22 is a schematic illustration of a high-speed output driver 900. In one embodiment, the output driver 900 is used as the CML drivers 374, 376 to output high-speed data or clock. The output driver 900 comprises a first current source network 901, a second current source network 902, and a current mode logic (CML) output stage 903. The high-speed output driver 900 further comprises a negative differential input terminal 904, a negative differential output terminal 914, a positive differential input terminal 905, and a positive differential output terminal 915.

The first current source network 901, in one embodiment, is half of a first stage circuit which controls its output voltage level with a first active element to pull the output voltage high and a second active element to pull the output voltage low. In one embodiment, the first current source network 901 comprises a plurality of n-channel bipolar junction transistors (BJT) devices 930, 931, 932 for high-speed operation. The BJT device 930 generates inverting and non-inverting versions of an input signal to drive the respective BJT devices 931, 932. The BJT devices 931, 932 pull the output of the first current source network 901 high or low respectively.

In the embodiment shown in FIG. 22, the base terminal of the BJT 930 is coupled to the negative input terminal 904 of the output driver 900. In addition, the collector terminal of the BJT 930 is coupled to the base terminal of the BJT 931 via a node 950, and the emitter terminal of the BJT 930 is coupled to the base terminal of the BJT 932 via a node 951. A power voltage source 920 is coupled to the first terminal of a resistor (R1) 940, and the second terminal of the resistor (R1) 940 is coupled to the node 950. The node 951 is further coupled to a first terminal of a resistor (R2) 941, and the second terminal of the resistor (R2) 941 is coupled to a positive terminal of a first biasing current source 910, which is approximately a 3 mA current source in one embodiment, wherein the negative terminal of the biasing current source 910 is coupled to a reference voltage source, such as a common ground terminal 925. The collector terminal of BJT 931 is coupled to the voltage source 920, and the emitter terminal of the BJT 931 is coupled to a node 952, wherein the collector terminal of BJT 932 is also coupled to the node 952. The emitter terminal of the BJT 932 is coupled to the positive terminal of a second biasing current source 911, which is relatively larger than the first biasing current source 910 and approximately a 10 mA current source in one embodiment, wherein the negative terminal of the biasing current source 911 is coupled to the common ground terminal 925.

The second current source network 902 is the other half of the first stage circuit and a mirror of the first current source network 901 (i.e., structurally and functionally similar to the first current source network 901). In one embodiment, the second current source network 902 comprises a plurality of n-channel bipolar junction transistors (BJT) devices 933, 934, 935, wherein the base terminal of the BJT 933 is coupled to the positive input terminal 905 of the output driver 900. In addition, the collector terminal of the BJT 933 is coupled to the base terminal of the BJT 934 via a node 953, and the emitter terminal of the BJT 933 is coupled to the base terminal of the BJT 935 via a node 954. The power voltage source 920 is coupled to the first terminal of a resistor (R3) 942, and the second terminal of the resistor (R3) 942 is coupled to the node 953. The node 954 is further coupled to the first terminal of a resistor (R4) 943, and the second terminal of the resistor (R4) 943 is coupled to the positive terminal of the first biasing current source 910, wherein the negative terminal of the biasing current source 910 is coupled to a common ground terminal 925. The collector terminal of BJT 934 is coupled to the voltage source 920, and the emitter terminal of the BJT 934 is coupled to a node 955, wherein the collector terminal of BJT 935 is also coupled to the node 955. The emitter terminal of the BJT 935 is coupled to the positive terminal of the second biasing current source 911, wherein the negative terminal of the biasing current source 911 is coupled to the common ground terminal 925.

The configuration of the BJT devices 930, 931, 932 in the first current source network and the configuration of the BJT devices 933, 934, 935 in the second current source network offer increased efficiency, high-speed transitioning and increased equalization of rise and fall response times. For example, depending on the polarity of the input voltage at the negative differential input terminal 904, the BJT 930 selectively activates either the BJT 931 or the BJT 932, thereby providing either a path from the power voltage source 920 or a path from the common ground terminal 925 to the input of the current mode logic output stage 903. In one embodiment, the high-speed output driver 900 is realized on an integrated circuit with n-type or n-channel transistors which react relatively quickly to changes and are easily matched for substantially identical operation.

The current mode logic (CML) output stage 903, in one embodiment, comprises a differential pair of n-channel BJT devices 936, 937, wherein the base terminal of the BJT 936 is coupled to the first current source network 901 via the node 952, and the base terminal of the BJT 937 is coupled to the second current source network 902 via the node 955. In addition, the negative differential output terminal 914 is coupled to the collector terminal of the BJT 936 via a node 956, and the positive differential output terminal 915 is coupled to the collector terminal of the BJT 937 via a node 957. The voltage source 920 is coupled to the first terminal of a first 100 ohm resistor (R5) 944, and the second terminal of the resistor (R5) 944 is coupled to the node 956. The voltage source 920 is also coupled to the first terminal of a second 100 ohm resistor (R6) 945, and the second terminal of the resistor (R6) 945 is coupled to the node 957. The emitter of the BJT 936 and the emitter of BJT 937 are both coupled to a node 958, wherein the node 958 is coupled to the positive terminal of a third biasing current source 912, which is approximately a 30 mA current source in one embodiment. Further, the negative terminal of the biasing current source 912 is coupled to the common ground terminal 925.

In one embodiment, the CML current network 903 comprises a differential pair of significantly matched BJT devices 936, 937 that exhibit similar properties such as structure, composition, and beta values. The emitters of the differential pair 936, 937 are joined together and are biased by the substantially constant 30 mA current source 912. In addition, the embodiment of the differential pair 936, 937 is configured to respond to differential signals from the differential input terminals 904, 905. For example, when the voltage potential at the base terminal of the BJT 936 is greater than the voltage potential at the base terminal of the BJT 937, the differential pair 936, 937 senses the differential input and responds by allowing current to flow through the BJT 936. Therefore, with relatively small difference voltages applied to the differential inputs 904, 905, the circuit is capable of directing the biasing current 912 from one side of the differential pair 936, 937 to the other side, wherein a difference voltage of about 100 mV may be sufficient to switch a considerable amount of the biasing current 912 to one side of the differential pair 936, 937.

The concept that a small signal may switch the current from one side of the differential pair 936, 937 to the other side describes a rapid current controlled switching effect, which is defined by the term Current Mode Logic (CML). Another reason for the high-speed switching operation of the differential pair 936, 937 is that the two BJT devices 936, 937 rarely enter into the saturation region of operation. As a result, the absence of saturation in the differential pair 936, 937 improves the switching speed by reducing the need for the removal of stored charge in the base, which may act as a capacitor that tends to store charge when a BJT is in saturation, wherein this absence of stored charge makes the CML family a fast switching logic circuit.

In one aspect, when the voltage potential at the negative differential input 904 is negative, the BJT 930 is non-operational, and the current through the resistor (R1) 940 is directed to conduct through the node 950 to the base terminal of BJT 931. Since the BJT 930 is off, the node 951 is pulled low turning the BJT 932 off. Thus, there is no current flowing through the BJT 932.

Correspondingly, the voltage potential at the positive differential input 905 is complementary to the negative input 904. A positive voltage at the differential input 905 turns the BJT 933 on, which allows current to conduct through the resistor (R3) 942. Since the BJT 933 is on or conducting current, the node 953 is pulled low turning off the BJT 934, and the node 954 is pulled high turning on the BJT 935. As the BJT 935 turns on, the node 955 is pulled low through the BJT 935 while the node 952 is pulled high through the BJT 931. As a result, the voltage potential at the positive differential output terminal 915 is pulled high while the voltage potential at the negative differential output terminal 914 is pulled low.

A similar situation occurs as the voltage potentials at the differential inputs 904, 905 switch to relative complementary states, wherein the above situation is reversed. A positive voltage potential may be applied to the negative differential input 904 and a negative voltage potential may be applied to the positive differential input 905, which provides for a positive voltage potential at the negative differential output 914 and a negative voltage potential at the positive differential output 915, respectively.

For example, a positive input voltage at the input terminal 904 develops a positive output voltage at the output terminal 914, and the complementary negative voltage input at the input terminal 905 develops a negative output voltage at the output terminal 915. As the input 904 switches from a positive voltage state to a negative state and the input 905 switches from a negative voltage state to positive voltage state, a current mode logic differential output is generated depending on the switching condition. In one embodiment, when the magnitude of the differential output is positive, then the logic value is a one. Conversely, when the magnitude of the differential output is negative, then the logic value is a zero. Noise may shift the DC component, but the voltage differential remains substantially the same. As a result, the logic state is substantially insulated from noise interference due to the utilization of the voltage differential for the current mode logic output state. It should be appreciated that, in another embodiment, when the magnitude of the differential output is positive, then the logic value could be a zero, and, conversely, when the magnitude of the differential output is negative, then the logic value could be a one.

From the foregoing, it will be appreciated that the high-speed output driver of the various described embodiments provides improved driving circuitry by improving the overall current efficiency of the output device, enhancing the reliability of differential outputs by improving the rise and fall response times during switching between polarity states. Furthermore, the multiple gain stages provide a high power output at each gain stage including the output stage, which also improves the rise and fall transitioning times due to the increased ability to rapidly drive the transistors during switching transitions.

Various embodiments of the invention have been described above. Although this invention has been described with reference to these specific embodiments, the descriptions are intended to be illustrative of the invention and are not intended to be limiting. Various modifications and applications may occur to those skilled in the art without departing from the true spirit and scope of the invention as defined in the appended claims.

### Appendix A

### Incorporation by Reference of Commonly Owned Applications

The following patent applications, commonly owned and filed on the same day as the present application, are hereby incorporated herein in their entirety by reference thereto:

| | | |
|---|---|---|
| | Application | Attorney |
| Title | No. | Docket No. |

| | |
|---|---|
| “Integration and Hold Phase Detection” | CCOM.003A |
| “Current Mode Phase Detection” | CCOM.004A |
| “Trigger Circuit” | CCOM.005A |
| “Two-Stage Multiplier Circuit” | CCOM.006A |
| “Reset Circuit” | CCOM.007A |
| “Multiplier Circuit” | CCOM.008A |
| “Data Transition Identifier” | CCOM.009A |
| “Frame Pattern Detection in an Optical | CCOM.016A |
| Receiver” | |
| “Single to Differential Input Buffer | CCOM.017A |
| Circuit” | |
| “Acquisition Aid Circuit” | CCOM.018A |
| “Low Voltage Differential Signaling | CCOM.019A |
| Output Buffer” | |
| “Low Frequency Loop-Back in a High- | CCOM.020A |
| Speed Optical Transceiver” | |
| “Phase Frequency Detector” | CCOM.021A |
| “Phase Alignment of Data to Clock” | CCOM.022A |
| “Voltage Controlled Oscillator” | CCOM.023A |
| “System and Method of Tuning a Voltage | CCOM.025A |
| Controlled Oscillator” | |
| “High-Speed Output Driver” | CCOM.026A |

What is claimed is:

1. A voltage controlled oscillator receiving a reference clock signal produced by a reference clock, the oscillator comprising:
an oscillation circuit that provides an oscillating signal at an output, wherein the oscillation circuit includes at least one adjustable component that is adjustable so as to result in changes in the frequency of the oscillating signal; and
at least a first frequency adjustment stage that includes a first counter that receives the oscillating signal and a second counter that receives the reference clock signal, wherein the frequency adjustment stage compares the output of the first and the second counters and produces an adjustment signal that is provided to the oscillation circuit so as to adjust the at least one adjustable component to thereby induce the oscillating signal to correspond to the reference signal.

2. The voltage controlled oscillator of claim 1, wherein the correspondence between the oscillating signal and the reference clock signal is a one to one correspondence.

3. The voltage controlled oscillator of claim 1, wherein the frequency adjustment stage sequentially compares the output of the first and the second counters and increments the frequency of the oscillating signal until the frequency of the oscillating signal is at least as great as the frequency of the reference clock signal.

4. The voltage controlled oscillator of claim 3, wherein the frequency adjustment stage first compares the output of the first and second counters and increments the frequency of the oscillating signal in discrete steps until the frequency of the oscillating signal is at least as great as the frequency of the reference clock signal and then adjusts the frequency of the oscillating signal in an analog manner to induce the oscillating signal to correspond to the reference clock signal.

5. The voltage controlled oscillator of claim 1, wherein the oscillation circuit includes a inductive element and a negative resistance element.

6. The voltage controlled oscillator of claim 5, wherein the negative resistance element comprises a transistor.

7. The voltage controlled oscillator of claim 1, wherein the at least one adjustable component comprises a variable capacitor.

8. The voltage controlled oscillator of claim 1, wherein the at least one adjustable component comprises a first adjustable component and a second adjustable component wherein the second adjustable component is adapted to operate with differential control signals.

9. The voltage controlled oscillator of claim 8, further comprising a second frequency adjustment stage wherein the second frequency adjustment stage provides the differential control signal.

10. The voltage controlled oscillator of claim 1, wherein the counters automatically reset to zero upon overflowing and wherein the first counter is reset in a slave relationship by the second counter upon an overflow condition of the second counter.

11. The voltage controlled oscillator of claim 1, wherein the first frequency adjustment stage further comprises a comparison and hold network wherein the comparison and hold network maintains the current adjustment signal until the comparison and hold network determines that the adjustment signal needs to be adjusted.

12. The voltage controlled oscillator of claim 11, wherein the comparison and hold network comprises a plurality of flip-flops and gates.

13. The voltage controlled oscillator of claim 1, wherein the first frequency adjustment stage further comprises an adjustment signal generator.

14. The voltage controlled oscillator of claim 13, wherein the adjustment signal generator comprises a shift register generating a plurality of control words and further comprising a plurality of voltage sources wherein the plurality of voltage sources generate a plurality of discrete control voltages corresponding to each of the plurality of control words.

15. A method of regulating a voltage controlled oscillator, the method comprising the steps of:
(i) operating the voltage controlled oscillator at a starting oscillator frequency;
(ii) conducting a first race between the oscillator and a reference clock having a frequency, wherein the oscillator frequency is compared to the reference clock frequency;
(iii) increasing the frequency of the voltage controlled oscillator by a set amount when race results indicates that the reference clock is faster than the oscillator; and
(iv) repeating steps (ii) and (iii) until the frequency of the voltage controlled oscillator is at least as fast as the frequency of the reference clock.

16. The method of claim 15, wherein the voltage controlled oscillator is used in a clock multiply unit to generate a differential output clock which is a multiple of the reference clock.

17. The method of claim 15, wherein the race is conducted using two counters coupled to the oscillator and the reference clock respectively.

18. The method of claim 15, further comprising the step of
(v) comparing the oscillator frequency to the reference clock frequency and adjusting the oscillator frequency such that the oscillator frequency corresponds to the reference clock frequency.

19. The method of claim 18, wherein correspondence between the oscillator frequency and the reference clock frequency comprises a one to one correspondence between the frequency and phase of the oscillator and the reference clock.

20. A method of performing an automatic search for an operating frequency range of a voltage controlled oscillator, the method comprising:
dividing frequencies into a plurality of overlapping ranges;
starting the voltage controlled oscillator with an oscillation frequency corresponding to a midpoint in the lowest range;
comparing an output signal of the voltage controlled oscillator with a reference signal;
increasing the oscillation frequency to correspond to a midpoint of the next higher range if the frequency of the output signal is lower than the frequency of the reference signal; and
repeating the comparison of the output signal to the reference signal and consequent increase in the oscillation frequency to correspond to the midpoint of the next higher range until the frequency of the output signal is higher than the frequency of the reference signal.

21. The method of claim 20, wherein the automatic search occurs upon powering up the voltage controlled oscillator.

22. The method claim 20, wherein the automatic search is implemented with digital circuitry.

23. The method of claim 22, wherein a substantial portion of the digital circuitry is disabled at the end of the automatic search.

24. A method of determining the operating frequency range of a voltage controlled oscillator, the method comprising:
dividing frequencies into a plurality of frequency ranges;
comparing an output signal of the voltage controlled oscillator with a reference signal;
increasing the oscillation frequency to correspond to a frequency within a next higher frequency range if the frequency of the output signal is lower than the frequency of the reference signal; and
repeating the comparison of the output signal to the reference signal and consequent increase in the oscillation frequency to correspond to a frequency within the next higher frequency range until the frequency of the output signal is higher than the frequency of the reference signal.

25. A digital circuit for initializing a voltage controlled oscillator, the digital circuit comprising:
a first counter incremented by a reference clock;
a second counter incremented by an internal clock generated by the voltage controlled oscillator;
a comparison circuit which detects occurrences of overflows in the first and second counters; and
an n-bit shift register with one of the bits initialized to ‘1’ and the remaining bits initialized to zero, wherein the n-bit shift register is shifted by one bit when the overflow of the first counter leads the overflow of the second counter in a specified time interval.

26. The digital circuit of claim 25, wherein the first counter periodically resets the second counter.

27. The digital circuit of claim 25, wherein the first counter, the second counter, and the comparison circuit are disabled after a predetermined time.

28. The digital circuit of claim 25, wherein position of the ‘1’ in the n-bit shift register determines a voltage level of a control signal applied to the voltage controlled oscillator.

29. The digital circuit of claim 25, wherein the digital circuit has a manual mode wherein the n-bit shift register is directly controlled by an input signal.

30. A method of initializing a voltage controlled oscillator, the method comprising:
operating the voltage controlled oscillator at a starting frequency;
conducting a race between a generated clock and a reference clock for a first interval, wherein the generated clock is referenced to the voltage controlled oscillator output;
increasing the frequency of the voltage controlled oscillator by a set amount when race results indicates that the reference clock is faster than the generated clock;
repeating the race and any frequency increase resulting from the race results after a second interval, wherein the repetitions occur for a predetermined number of times.

31. The method of claim 30, wherein the voltage controlled oscillator is used in a clock multiply unit to generate a differential output clock which is a multiple of the reference clock.

32. The method of claim 30, wherein the race is conducted using two counters coupled to the generated clock and the reference clock respectively.
